(19) United States
(12) Patent Application Publication
(10) Pub. No.: US 2023/0030366 A1
(43) Pub. Date: Feb. 2, 2023

(54) SURFACE STRESS SENSOR AND METHOD FOR MANUFACTURING SAME

(71) Applicant: ASAHI KASEI KABUSHIKI KAISHA, Tokyo (JP)

(72) Inventors: Takanori MURAKAMI, Tokyo (JP); Hiroyuki TSUJIMOTO, Tokyo (JP); Kenjiro OKUNO, Tokyo (JP)

(73) Assignee: ASAHI KASEI KABUSHIKI KAISHA, Tokyo (JP)

(21) Appl. No.: 17/790,536

(22) PCT Filed: Jan. 4, 2021
(86) PCT No.: PCT/JP2021/000037

§ 371 Date: Jul. 1, 2022

(30) Foreign Application Priority Data
Jan. 9, 2020 (JP) 2020-002329

(51) Int. Cl. G01L 1/22

(52) U.S. Cl. CPC G01L 1/2293

(57) ABSTRACT

A surface stress sensor in which a surface of a membrane includes a receptor forming region that is a region including the center of the surface and an exterior region that is a region located closer to a holding member than the receptor forming region, that includes a forming region-side recess/protrusion pattern that is formed in the receptor forming region and is formed with a pattern in which a plurality of protruding portions or a plurality of recessed portions continue, and in which the forming region-side recess/protrusion pattern is a pattern having a degree of roughness that allows a solution to be present in gaps formed by the plurality of protruding portions or the plurality of recessed portions forming the forming region-side recess/protrusion pattern.

### TECHNICAL FIELD

The present invention relates to a surface stress sensor, in particular, a membrane-type surface stress sensor (MSS) that has high sensitivity compared with a piezoresistive cantilever-type sensor, and a method for manufacturing the surface stress sensor.

### BACKGROUND ART

Examples of technology used for a sensor for collecting information equivalent to the five senses of a human, in particular, a sensor of taste or smell, which a human senses by receiving a chemical substance, include a technology of a surface stress sensor including a piezoresistive member, which is disclosed in PTL 1.

In the technology disclosed in PTL 1, a layer of a solute is formed by applying and drying, for example, a polyethylenimine (PEI) solution to the upper side (front surface) of a planar member by means of an inkjet-spotting technology, and a receptor that adsorbs an analyte is formed.

### CITATION LIST

### Patent Literature

PTL 1: WO 2011/148774 A

### SUMMARY OF INVENTION

### Technical Problem

However, as described in PTL 1, both a receptor forming region in which a receptor is formed and a region (exterior region) on the outer side of the receptor forming region on the surface of the planar member have the same affinity for a solution. Thus, a portion of a solution applied to the receptor forming region spills out from the receptor forming region to the exterior region, and there is a possibility that a problem in that it is difficult to control the shape of the receptor to be formed in a desired shape (for example, perfect circular cylinder) may occur.

The present invention has been made in view of the conventional unsolved problem described above, and an object of the present invention is to provide a surface stress sensor that enables controllability to control a receptor to be formed in a desired shape to be improved and a method for manufacturing the surface stress sensor.

### Solution to Problem

In order to achieve the above-described object, a surface stress sensor according to one aspect of the present invention includes a membrane, a holding member, at least a pair of coupling portions, a flexible resistor, a receptor, and a forming region-side recess/protrusion pattern. The membrane is configured to be bent by applied surface stress. The holding member is arranged on the outer side of the membrane. The coupling portions are configured to couple the membrane and the holding member. The flexible resistor is configured to have a resistance value changing according to bending induced in the coupling portions. The forming region-side recess/protrusion pattern is formed on the surface of the membrane and formed with a pattern in which a plurality of protruding portions or a plurality of recessed portions continue. In addition, the surface of the membrane includes a first surface region that is a region including the center of the surface and a second surface region that is a region located closer to the holding member than the first surface region. In addition, the forming region-side recess/protrusion pattern is a pattern that is formed in the first surface region within the surface of the membrane and that has a degree of roughness that allows a solution to be present in gaps formed by the plurality of protruding portions or the plurality of recessed portions that form the forming region-side recess/protrusion pattern.

In addition, a method for manufacturing a surface stress sensor according to another aspect of the present invention includes a forming region-side recess/protrusion pattern formation step. The forming region-side recess/protrusion pattern formation step is a step of forming a forming region-side recess/protrusion pattern that is formed with a pattern in which a plurality of protruding portions or a plurality of recessed portions continue in a first surface region that is a preset region including the center of a surface that is one surface of a detection base member. In the forming region-side recess/protrusion pattern formation step, the forming region-side recess/protrusion pattern is formed in such a way that the forming region-side recess/protrusion pattern has a degree of roughness that allows a solution to be present in gaps formed by the plurality of protruding portions or the plurality of recessed portions forming the forming region-side recess/protrusion pattern.

### Advantageous Effects of Invention

According to the one aspect of the present invention, forming the forming region-side recess/protrusion pattern on the first surface region within the surface of the membrane causes the affinity of the first surface region for a solution to be higher than the affinity of the second surface region for the solution.

Since, because of this capability, it becomes possible to prevent the solution applied to the first surface region from spilling out to the second surface region, it becomes possible to provide a surface stress sensor that enables controllability to control the receptor to be formed in a desired shape to be improved and a method for manufacturing the surface stress sensor.

### BRIEF DESCRIPTION OF DRAWINGS

FIG. 1 is a side view illustrative of a configuration of a surface stress sensor according to a first embodiment of the present invention;

FIG. 2 is a diagram viewed from the arrow II in FIG. 1;

FIG. 3 is a cross-sectional view taken along the line III-III in FIG. 2;

FIG. 4 is a cross-sectional view taken along the line IV-IV in FIG. 2;

FIG. 5 is a perspective view of the surface stress sensor;

FIG. 6 is a diagram viewed from an arrow similar to the diagram viewed from the arrow II in FIG. 1 and a plan view of a membrane;

FIG. 7 is a cross-sectional view taken along the line VII-VII in FIG. 2;

FIG. 8 is a perspective view of an area VIII enclosed by a dashed line in FIG. 7;

FIG. 9 is a diagram illustrative of a relationship between a shape of a forming region-side recess/protrusion pattern and lyophilicity;

FIG. 10 is another diagram illustrative of the relationship between the shape of the forming region-side recess/protrusion pattern and the lyophilicity;

FIG. 11 is still another diagram illustrative of the relationship between the shape of the forming region-side recess/protrusion pattern and the lyophilicity;

FIG. 12 is a diagram illustrative of a configuration of a sample membrane used in verification and examination of lyophilicity;

FIG. 13 is a cross-sectional view taken along the line XIII-XIII in FIG. 12;

FIGS. 14A to 14C are diagrams illustrative of variations of a configuration of the membrane and an exterior region-side recess/protrusion pattern;

FIGS. 15A to 15C are diagrams illustrative of other variations of the configuration of the membrane and the exterior region-side recess/protrusion pattern;

FIGS. 16A to 16C are diagrams illustrative of still other variations of the configuration of the membrane and the exterior region-side recess/protrusion pattern;

FIGS. 17A and 17B are diagrams illustrative of a variation of the exterior region-side recess/protrusion pattern, and FIGS. 17A and 17B are a plan view and a cross-sectional view taken along the line b-b in FIG. 17A, respectively;

FIGS. 18A and 18B are diagrams illustrative of another variation of the exterior region-side recess/protrusion pattern, and FIGS. 18A and 18B are a plan view and a cross-sectional view taken along the line b-b in FIG. 18A, respectively;

FIGS. 19A and 19B are diagrams illustrative of still another variation of the exterior region-side recess/protrusion pattern, and FIGS. 19A and 19B are a plan view and a cross-sectional view taken along the line b-b in FIG. 19A, respectively;

FIGS. 20A and 20B are diagrams illustrative of a variation of the forming region-side recess/protrusion pattern and the exterior region-side recess/protrusion pattern, and FIGS. 20A and 20B are a plan view and a cross-sectional view taken along the line b-b in FIG. 20A, respectively;

FIGS. 21A and 21B are diagrams illustrative of another variation of the forming region-side recess/protrusion pattern and the exterior region-side recess/protrusion pattern, and FIGS. 21A and 21B are a plan view and a cross-sectional view taken along the line b-b in FIG. 21A, respectively;

FIGS. 22A and 22B are diagrams illustrative of still another variation of the forming region-side recess/protrusion pattern and the exterior region-side recess/protrusion pattern, and FIGS. 22A and 22B are a plan view and a cross-sectional view taken along the line b-b in FIG. 22A, respectively;

FIGS. 23A and 23B are diagrams illustrative of still another variation of the forming region-side recess/protrusion pattern and the exterior region-side recess/protrusion pattern, and FIGS. 23A and 23B are a plan view and a cross-sectional view taken along the line b-b in FIG. 23A, respectively;

FIGS. 24A and 24B are diagrams illustrative of a stacked body formation step;

FIG. 25 is a diagram illustrative of a first ion implantation step and a second ion implantation step;

FIGS. 26A and 26B are diagrams illustrative of a wiring layer formation step;

FIGS. 27A and 27B are other diagrams illustrative of the wiring layer formation step;

FIGS. 28A and 28B are still other diagrams illustrative of the wiring layer formation step;

FIGS. 29A and 29B are still other diagrams illustrative of the wiring layer formation step;

FIGS. 30A and 30B are still other diagrams illustrative of the wiring layer formation step;

FIGS. 31A to 31C are cross-sectional views taken along the line Y-Y in FIG. 2 and diagrams illustrative of a forming region-side recess/protrusion pattern formation step, an exterior region-side recess/protrusion pattern formation step, and a removal step;

FIGS. 32A and 32B are diagrams illustrative of a variation of the first embodiment, and FIGS. 32A and 32B are a plan view and a cross-sectional view taken along the line b-b in FIG. 32A, respectively;

FIGS. 33A and 33B are diagrams illustrative of another variation of the first embodiment, and FIGS. 33A and 33B are a plan view and a cross-sectional view taken along the line b-b in FIG. 33A, respectively;

FIGS. 34A and 34B are diagrams illustrative of still another variation of the first embodiment, and FIGS. 34A and 34B are a plan view and a cross-sectional view taken along the line b-b in FIG. 34A, respectively;

FIGS. 35A and 35B are diagrams illustrative of still another variation of the first embodiment, and FIGS. 35A and 35B are a plan view and a cross-sectional view taken along the line b-b in FIG. 35A, respectively;

FIG. 36 is a diagram illustrative of still another variation of the first embodiment;

FIG. 37 is a diagram illustrative of still another variation of the first embodiment;

FIG. 38 is a diagram illustrative of still another variation of the first embodiment;

FIG. 39 is a diagram illustrative of still another variation of the first embodiment;

FIG. 40 is a diagram illustrative of still another variation of the first embodiment;

FIG. 41 is a side view illustrative of a configuration of a surface stress sensor according to a second embodiment of the present invention;

FIG. 42 is a diagram illustrative of a stacked body formation step;

FIG. 43 is a diagram illustrative of a hole formation step;

FIG. 44 is a diagram illustrative of a cavity portion formation step;

FIG. 45 is a diagram illustrative of a hole sealing step;

FIG. 46 is a plan view illustrative of a configuration of a surface stress sensor according to a third embodiment of the present invention;

FIG. 47 is a cross-sectional view taken along the line A-A in FIG. 46;

FIG. 48 is a cross-sectional view taken along the line B-B in FIG. 46;

FIG. 49 is a cross-sectional view illustrative of a detailed configuration of a forming region-side recess/protrusion pattern and an exterior region-side recess/protrusion pattern;

FIG. 50 is a diagram illustrative of a variation of the third embodiment; and

FIG. 51 is a diagram viewed from the arrow VXI in FIG. 50.

### DESCRIPTION OF EMBODIMENTS

Embodiments of the present invention are explained below with reference to the drawings. In the description of the drawings referred to in the following explanation, the same or similar parts are marked with the same or similar signs. However, it should be noted that the drawings are schematic, and the relationship between thicknesses and plane dimensions, thickness ratios, etc., may differ from reality. Therefore, specific thickness and dimensions should be determined by referring to the following explanation. In addition, it is of course possible that some parts of the drawings have different dimensional relationships and proportions to each other.

Furthermore, the following embodiments are examples of configurations for embodying the technical idea of the present invention, and the technical idea of the present invention does not specify materials of constituent components, their shapes, structures, and arrangements, etc., to the following ones. The technical idea of the present invention can be modified in various ways within the technical scope defined by the patent claims. The directions of “left and right” or “up and down” in the following description are merely definitions for convenience of explanation, and do not restrict the technical concept of the present invention. Accordingly, for example, if the paper is rotated 90 degrees, “left and right” and “up and down” are read interchangeably, and if the paper is rotated 180 degrees, “left” becomes “right” and “right” becomes “left,” of course.

### First Embodiment

Hereinafter, a first embodiment of the present invention will be described with reference to the drawings.

### (Configuration)

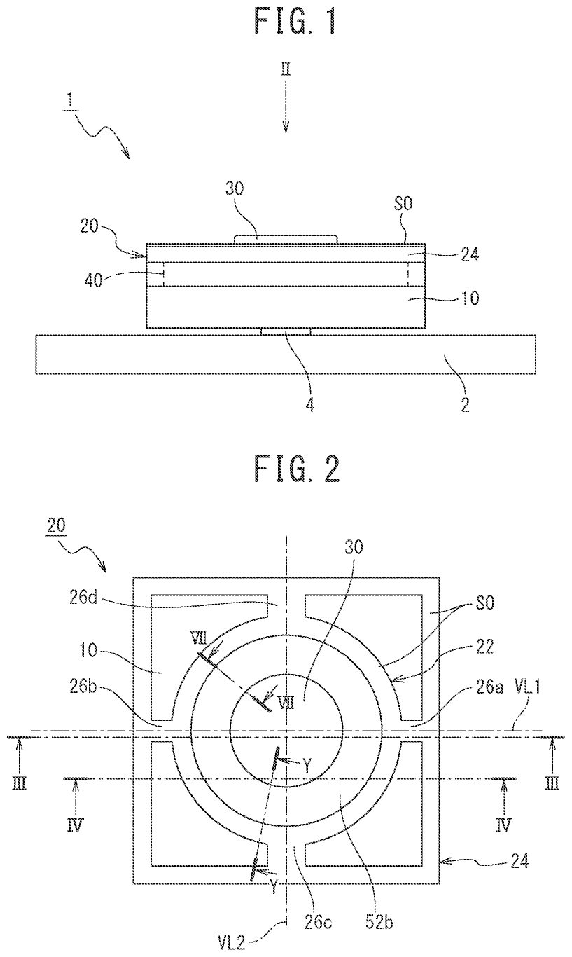

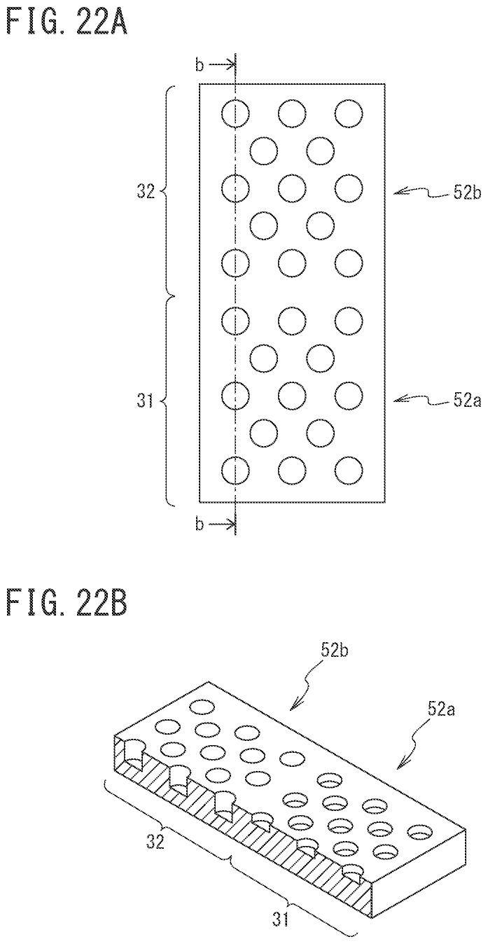

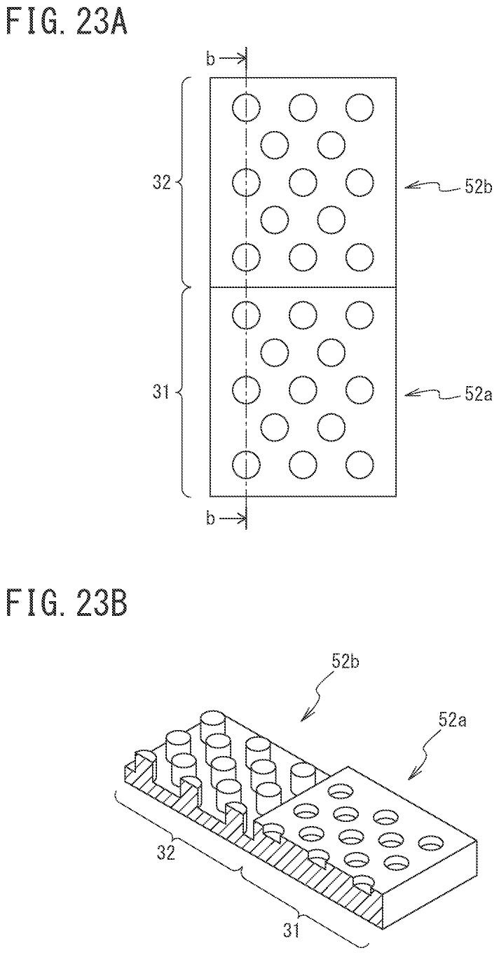

Using FIGS. 1 to 23B, a configuration of the first embodiment will be described.

A surface stress sensor 1 illustrated in FIGS. 1 to 8 is used in, for example, sensors that detect taste or smell and includes a package substrate 2, a connecting portion 4, a detection base member 20, and a support base member 10. Note that, in FIG. 2, illustration of the package substrate 2 and the connecting portion 4 is omitted for the purpose of clarity.

### (Package Substrate)

The package substrate 2 is formed of, for example, a metal, a polymer, a ceramic material or the like and is formed with, for example, a thickness in the order of millimeters.

### (Connecting Portion)

The connecting portion 4 is arranged on one surface (in FIG. 1, the surface on the upper side) of the package substrate 2 and is formed using, for example, an adhesive agent or solder.

In the first embodiment, a case where the shape of the connecting portion 4 is formed in a circle will be described as an example.

### (Detection Base Member)

The detection base member 20 is stacked on one surface (in FIG. 1, the surface on the upper side) of the support base member 10 and is formed by a membrane 22, a holding member 24, and coupling portions 26 integrated with one another.

In the first embodiment, a case where silicon is used as a material of which the detection base member 20 is formed will be described as an example.

In addition, as a material of which the detection base member 20 is formed, a material that causes a difference between a value of a linear expansion coefficient of the support base member 10 and a value of a linear expansion coefficient of the detection base member 20 to be 1.2×10⁻⁵/° C. or less is used.

In the first embodiment, a case where the same material is used as a material of which the detection base member 20 is formed and a material of which the support base member 10 is formed will be described.

### (Membrane)

The membrane 22 is formed in a plate shape.

In the first embodiment, a case where the membrane 22 is formed in a disc shape will be described as an example.

In addition, the membrane 22 is an n-type semiconductor layer.

In addition, on one surface (in FIG. 1, the surface on the upper side) of the membrane 22, an oxide film SO (silicon oxide film) is formed. Note that, in the following description, the one surface of the membrane 22 is sometimes referred to as “front surface of the membrane 22”.

The oxide film SO is not limited to silicon oxide film as long as the oxide film SO is a material having high wettability for a receptor.

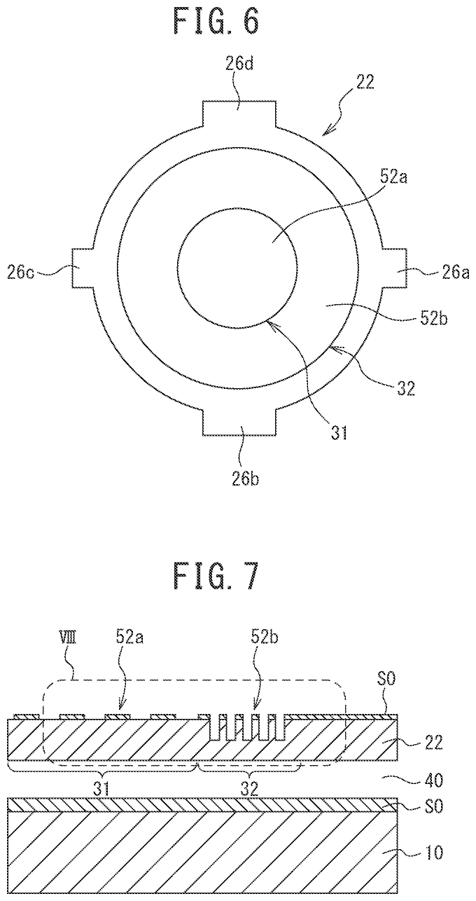

Further, the front surface of the membrane 22 has a receptor forming region (first surface region) 31 and an exterior region (second surface region) 32, as illustrated in FIG. 6. Note that, although FIG. 6 is, as with FIG. 2, a plan view of the surface stress sensor 1, only the membrane 22 and the coupling portions 26 are illustrated for the purpose of clarity.

The receptor forming region 31 is a region that includes the center of the front surface of the membrane 22 and is set in advance. In addition, the receptor forming region 31 is a region that serves as a rough target in forming a receptor 30, which will be described later. Note that a region in which the receptor 30 is actually formed within the receptor forming region 31 may be set to the whole of the receptor forming region 31 or only a portion of the receptor forming region 31. In addition, the region in which the receptor 30 is actually formed within the receptor forming region 31 may be set to a region including, in addition to the whole of the receptor forming region 31, a portion of the exterior region 32.

In the first embodiment, a case where the receptor forming region 31 is set to a region that forms a perfect circle when viewed from the thickness direction of the membrane 22 will be described as an example.

The exterior region 32 is a region that is located closer to the holding member 24 than the receptor forming region 31 and is set in advance.

In the first embodiment, a case where the exterior region 32 is set to a region that surrounds the circumference of the receptor forming region 31, which is a region that forms a perfect circle, over the entire circumference in a concentric manner when viewed from the thickness direction of the membrane 22 will be described as an example.

As illustrated in FIG. 7, a forming region-side recess/protrusion pattern 52a is formed in the receptor forming region 31, and an exterior region-side recess/protrusion pattern 52b is formed in the exterior region 32. In addition, although illustration is omitted, the forming region-side recess/protrusion pattern 52a and the exterior region-side recess/protrusion pattern 52b are formed on the oxide film SO. Note that details of the forming region-side recess/protrusion pattern 52a and the exterior region-side recess/protrusion pattern 52b will be described later.

In addition, the receptor 30 is applied to the receptor forming region 31. That is, the receptor forming region 31 is a region in which the receptor 30 is formed within the front surface of the membrane 22. Note that, since it is preferable that area of a region to which the receptor 30 is applied be large, it is preferable that the receptor forming region 31 be a large region.

The receptor 30 is formed by applying and drying a solution in which a resin formed from, although not specifically limited, polyethylenimine (PEI) or the like is dissolved (hereinafter, sometimes referred to as “PEI solution”). In addition, molecules of a gas adsorbing to the receptor 30 causes a strain to be induced in the receptor 30. The solution in which the receptor is dissolved is not specifically limited as long as the receptor can be dissolved in the solution, and a general organic solvent or water can be used as the solution.

When molecules of a gas adsorb to the receptor 30 and a strain is induced in the receptor 30, surface stress is applied to the membrane 22 and the membrane 22 is bent. Therefore, when molecules of a gas adsorb to the receptor 30, the membrane 22 is bent by applied surface stress.

Note that the configuration of the receptor 30 is not limited to the configuration in which adsorption of molecules of a gas causes a strain to be induced and may be, for example, a configuration in which magnetism causes a strain to be induced. That is, the configuration of the receptor 30 may be appropriately altered depending on a target to be detected by the surface stress sensor 1.

### (Holding Member)

The holding member 24 is arranged on the outer side of a center of the membrane 22. In addition, the holding member 24 is formed in a quadrilateral (square) frame shape and surrounds the membrane 22 with gaps interposed therebetween when viewed from the thickness direction of the membrane 22.

A viewpoint when viewed from the thickness direction of the membrane 22 is a viewpoint when the surface stress sensor 1 is viewed from above (in FIG. 1, a viewpoint when viewed from the direction of the arrow II).

When viewed from the thickness direction of the membrane 22, the center of the holding member 24 coincides with the center of the membrane 22.

In addition, the holding member 24 is connected to a surface (in FIG. 1, the surface on the upper side) of the support base member 10 on the opposite side to a surface thereof facing the package substrate 2, using one of various types of joining technology, such as adhesion.

In the first embodiment, a case where the shapes of the holding member 24 and the support base member 10 are formed in shapes that have the outer peripheral surfaces of the support base member 10 and the outer peripheral surfaces of the holding member 24 flush with each other when viewed from the thickness direction of the membrane 22 will be described as an example.

That is, the holding member 24 and the support base member 10 are quadrilaterals of the same shape when viewed from the thickness direction of the membrane 22. The same quadrilateral shape is achieved by, for example, after connecting the holding member 24 and the support base member 10 to each other, performing dicing processing on the holding member 24 and the support base member 10. That is, when viewed from the thickness direction of the membrane 22, the center of the holding member 24 coincides with the center of the support base member 10.

Therefore, when viewed from the thickness direction of the membrane 22, the support base member 10 overlaps the membrane 22 and the holding member 24.

Further, when viewed from the thickness direction of the membrane 22, the connecting portion 4 is arranged at a position at which the connecting portion 4 overlaps at least a portion of the membrane 22.

In addition, when viewed from the thickness direction of the membrane 22, area of the frame member 4 is smaller than area of the membrane 22.

In addition, the package substrate 2 is connected to a surface (in FIG. 1, the surface on the lower side) of the support base member 10 on the opposite side to a surface thereof facing the membrane 22.

### (Coupling Portion)

The coupling portions 26 are formed in belt shapes when viewed from the thickness direction of the membrane 22.

In addition, when viewed from the thickness direction of the membrane 22, the coupling portions 26 are arranged at positions at which the coupling portions 26 overlap virtual straight lines VL1 and VL2 passing the center of the membrane 22 and couple the membrane 22 and the holding member 24 to each other.

In the first embodiment, a case where the membrane 22 and the holding member 24 are coupled to each other with four coupling portions 26a to 26d constituting two pairs will be described as an example.

The four coupling portions 26a to 26d includes a pair of the coupling portions 26a and 26b that are arranged at positions at which the coupling portions 26a and 26b overlap the straight line VL1 and a pair of the coupling portions 26c and 26d that are arranged at positions at which the coupling portions 26c and 26d overlap the straight line VL2, which crosses the straight line VL1 at right angles.

That is, the pair of the coupling portions 26a and 26b and the pair of the coupling portions 26c and 26d are arranged at positions sandwiching the membrane 22 when viewed from the thickness direction of the membrane 22 and couple the membrane 22 and the holding member 24 to each other. Therefore, the holding member 24 holds the membrane 22 via the coupling portions 26.

In the first embodiment, a case where width of the coupling portions 26a and 26b is narrower than width of the coupling portions 26c and 26d will be described as an example.

Between the support base member 10, and the membrane 22 and four coupling portions 26a to 26d, a cavity portion 40 is disposed.

Therefore, the support base member 10 is arranged in such a manner as to be connected to the holding member 24 with a cavity (the cavity portion 40) disposed between the support base member 10, and the membrane 22 and coupling portions 26. In addition to the above, when viewed from the thickness direction of the membrane 22, the support base member 10 overlaps the membrane 22 and the coupling portions 26.

Note that, when the surface stress sensor 1 is used in a solution, the cavity portion 40 may be filled with the solution.

The cavity portion 40 functions as a space that, when the membrane 22 is bent toward the side on which the support base member 10 is located during processing of the detection base member 20, prevents the membrane 22 from clinging to the support base member 10.

On the four coupling portions 26a to 26d, flexible resistors 50a to 50d are formed, respectively.

### (Flexible Resistor)

Each flexible resistor 50 has a resistance value that changes according to bending induced in a coupling portion 26 on which the flexible resistor 50 is formed.

In the first embodiment, a case where the flexible resistors 50 are formed of piezoresistors will be described as an example.

The piezoresistors are formed by, for example, implanting ions into the coupling portions 26 and have resistance values that change according to bending induced in the coupling portions 26 by the membrane 22 being bent.

In addition, the flexible resistors 50 are p-type semiconductor layers.

Among the four flexible resistors 50a to 50d, for example, flexible resistors 50 that are adjacent to each other (the coupling portion 26a and each of the coupling portions 26c and 26d and the coupling portion 26b and each of the coupling portions 26c and 26d) are connected to each other, as illustrated in FIG. 5. This configuration causes the four flexible resistors 50a to 50d to form a full Wheatstone bridge illustrated in FIG. 5.

### (Piezoresistor)

Hereinafter, a detailed configuration of a piezoresistor will be described.

A resistance value (R) of a piezoresistor and relative resistance change (ΔR/R) in the resistance value of the piezoresistor are given by the equations (1) to (3) below.

$$\begin{matrix}[ Math . 1 ] & \\ R = ρ \frac{l}{wl} & ( 1 )\end{matrix}$$

$$\begin{matrix}[ Math . 2 ] & \\ Δ R = \frac{\partial R}{\partial ρ} Δρ + \frac{\partial R}{\partial l} Δ l + \frac{\partial R}{\partial w} Δ w + \frac{\partial R}{\partial t} Δ t & ( 2 )\end{matrix}$$

$$\begin{matrix}[ Math . 3 ] & \\ \begin{matrix}\frac{Δ R}{R} = \frac{Δρ}{ρ} + \frac{Δ l}{l} - \frac{Δ w}{w} - \frac{Δ t}{t} \\ = ( {π}_{x} {σ}_{x} + {π}_{y} {σ}_{y} + {π}_{z} {σ}_{z} ) + {ε}_{x} - {ε}_{y} - {ε}_{z}\end{matrix} & ( 3 )\end{matrix}$$

In the equations (1) to (3), ρ, l, w, and t denote resistivity, length, width, and thickness of the piezoresistor, respectively, σ and ε denote stresses and strains induced in the piezoresistor, respectively, and n denotes piezoresistive coefficients.

In addition, in the equations (1) to (3), x, y, and z correspond to the longitudinal direction, lateral direction, and normal direction of a cantilever, respectively.

Relationships between the strains and the stresses can be derived from the generalized Hooke's law.

$$\begin{matrix}[ Math . 4 ] & \\ {ε}_{x} = \frac{l}{E} [ {σ}_{x} - v ( {σ}_{y} + {σ}_{z} ) ] & ( 4 )\end{matrix}$$

$$\begin{matrix}[ Math . 5 ] & \\ {ε}_{y} = \frac{l}{E} [ {σ}_{y} - v ( {σ}_{x} + {σ}_{z} ) ] & ( 5 )\end{matrix}$$

$$\begin{matrix}[ Math . 6 ] & \\ {ε}_{z} = \frac{l}{E} [ {σ}_{z} - v ( {σ}_{x} + {σ}_{y} ) ] & ( 6 )\end{matrix}$$

In the equations (4) to (6), E and ν denote a Young's modulus and a Poisson's ratio of the cantilever, respectively. Therefore, when it is assumed that the stress is plane stress (that is, σ_{z}=0), the relative resistance change can be expressed by the equation (7) below.

$$\begin{matrix}[ Math . 7 ] & \\ \frac{Δ R}{R} = {σ}_{x} ( \frac{1 + 2 v}{E} + {π}_{x} ) + {σ}_{y} ( - \frac{1}{E} + {π}_{y} ) & ( 7 )\end{matrix}$$

A piezoresistor that forms a p-type semiconductor layer by being formed using single-crystal Si (100) in order to gain a large signal and use a high piezo-coefficient that silicon has to the maximum extent possible will now be examined. The piezoresistive coefficients are determined by relationships that are expressed by the equations (8) and (9) below.

$$\begin{matrix}[ Math . 8 ] & \\ {π}_{x} = \frac{1}{2} ( {π}_{11} + {π}_{12} + {π}_{44} ) & ( 8 )\end{matrix}$$

$$\begin{matrix}[ Math . 9 ] & \\ {π}_{y} = \frac{1}{2} ( {π}_{11} + {π}_{12} - {π}_{44} ) & ( 9 )\end{matrix}$$

In the equations (8) and (9), π₁₁, π₁₂, and π₄₄ are fundamental piezoresistive coefficients of the crystal. When the silicon is p-type Si (100) the x-direction and y-direction of which are aligned with the [110] direction and the [1-10] direction, respectively, π₁₁ is +6.6 in units of 10⁻¹¹ Pa⁻¹. In addition to the above, π₁₂ and π₄₄ are −1.1 and +138.1, respectively, in units of 10⁻¹¹ Pa⁻¹.

Therefore, the piezoresistive coefficients πₓ and π_{y} are calculated to be 71.8×10⁻¹¹ Pa⁻¹ and −66.3×10⁻¹¹ Pa⁻¹, respectively. In addition, E and ν are 1.70×10¹¹ Pa and 0.28, respectively. Since πₓ>>(1+2 ν)/E, π_{y}>>−1/E, and πₓ≈−π_{y}≈π₄₄/2, the equation (7) can be approximated as indicated by the equation (10) below.

$$\begin{matrix}[ Math . 10 ] & \\ \frac{Δ R}{R} \approx \frac{1}{2} {π}_{44} ( {σ}_{x} - {σ}_{y} ) & ( 10 )\end{matrix}$$

Therefore, a signal from the piezoresistor (that is, ΔR/R) is mainly determined by a difference between σₓ and σ_{y}.

### (Forming Region-Side Recess/Protrusion Pattern)

The forming region-side recess/protrusion pattern 52a is formed in the receptor forming region 31 within the front surface of the membrane 22.

In addition, the forming region-side recess/protrusion pattern 52a is formed with a pattern in which a plurality of protruding portions (protrusions or pillars) or a plurality of recessed portions (openings or holes) are consecutively repeated. In the first embodiment, a case where each protruding portion and each recessed portion are formed in a circle pillar shape and a round opening, respectively, will be described as an example. Note that each protruding portion may be formed in, for example, a square pillar shape or a pyramid shape. In addition, each recessed portion may be formed in, for example, a polygonal opening or a groove.

In the first embodiment, a case where the forming region-side recess/protrusion pattern 52a is formed by a plurality of protruding portions (pillars) will be described as an example.

Further, in the first embodiment, a case where the plurality of protruding portions (pillars) forming the forming region-side recess/protrusion pattern 52a are formed in the same shape (outer diameter and height) will be described as an example.

In addition, in the first embodiment, a case where each of the protruding portions forming the forming region-side recess/protrusion pattern 52a is formed in a circle when viewed from the thickness direction of the membrane 22 will be described as an example. Note that the “circle” in which each of the protruding portions forming the forming region-side recess/protrusion pattern 52a is formed is not limited to a perfect circle and may be a round shape other than a perfect circle, such as an ellipse.

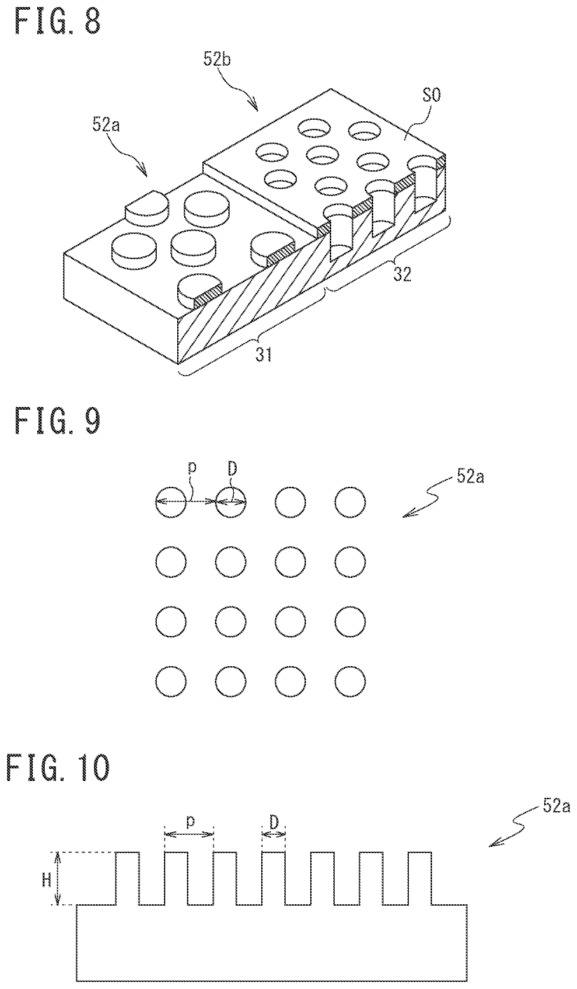

Note that, in FIG. 7, a cross-section of the forming region-side recess/protrusion pattern 52a is illustrated as a configuration in which a plurality of protruding portions are formed by illustrating only a cross-sectional view of a portion taken along the line VII-VII in FIG. 2 among the cross-sections of the forming region-side recess/protrusion pattern 52a for the purpose of clarity. However, an actual structure of the forming region-side recess/protrusion pattern 52a is a structure in which a plurality of protruding portions are arranged at intervals in an array, as illustrated in FIGS. 8 and 9.

Next, a specific configuration of the forming region-side recess/protrusion pattern 52a will be described.

As illustrated in FIG. 7, a cross-section of the forming region-side recess/protrusion pattern 52a is a shape in which protruding portions are arranged.

In addition, height H of each of the protruding portions forming the forming region-side recess/protrusion pattern 52a is set using, for example, the equations (11) and (12) below.

$$\begin{matrix}[ Math . 11 ] & \\ {P}_{L} = \frac{2 {γ}_{L}}{R} = \frac{16 {γ}_{L} δ}{{( \sqrt{2} p - D )}^{2}} & ( 11 )\end{matrix}$$

$$\begin{matrix}[ Math . 12 ] & \\ δ = \frac{{{P}_{L} ( \sqrt{2} p - D )}^{2}}{16 {γ}_{L}} & ( 12 )\end{matrix}$$

In the equations (11) and (12), “P_{L}” and “γ_{L}” denote Laplace pressure and surface tension at the gas-liquid interface, respectively. In addition, in the equations (11) and (12), “p” and “D” denote pitch between protruding portions adjacent to each other and outer diameter of each protruding portion, respectively, as illustrated in FIGS. 9 and 10.

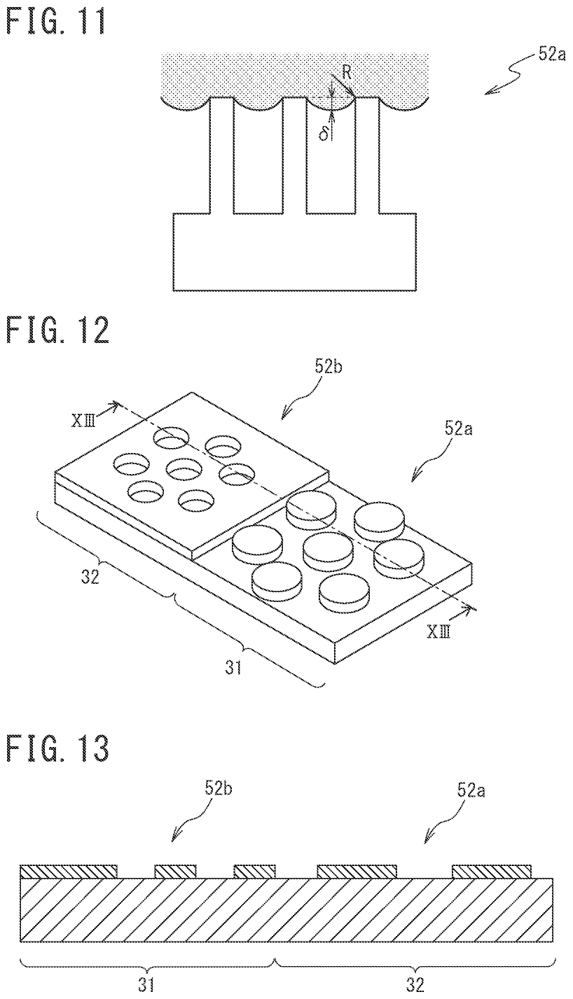

In addition, “R” in the equations (11) and (12) denotes a contact angle of a solution applied to the receptor forming region 31 with respect to a protruding portion, as illustrated in FIG. 11. Further, “8” in the equations (11) and (12) denotes a difference in height (thickness of a recess) between a point within the surface of the solution applied to an interspace between protruding portions adjacent to each other at which a difference in height from the tops of the protruding portions is largest (a point at which the surface is most recessed) and the tops of the protruding portions, as illustrated in FIG. 11.

From the equation (11), it is clear that the pitch p between protruding portions adjacent to each other is preferably set narrow in order to reduce the thickness δ of recesses and the higher the height H of the protruding portions is, the less likely the solution applied to interspaces between the protruding portions adjacent to each other is to infiltrate into the interspaces between the protruding portions adjacent to each other.

Therefore, forming the forming region-side recess/protrusion pattern 52a in such a way that a relational expression δ>H holds in the equation (11) enables lyophobicity of the receptor forming region 31 in which the forming region-side recess/protrusion pattern 52a is formed to be reduced. That is, forming the forming region-side recess/protrusion pattern 52a in such a way that the relational expression δ>H holds in the equation (11) enables lyophilicity of the receptor forming region 31 in which the forming region-side recess/protrusion pattern 52a is formed to be improved.

In addition, from the equation (12), it is clear that, as a difference between the pitch p between protruding portions adjacent to each other and the outer diameter D of protruding portions increases (as an interval between protruding portions adjacent to each other is set wider), it becomes possible to increase the thickness δ of recesses. Further, the lower the height H of protruding portions is with respect to liquid volume of the solution, the more greatly the receptor forming region 31 in which the forming region-side recess/protrusion pattern 52a is formed contributes to lyophilicity without exhibiting lyophobicity.

Consequently, the forming region-side recess/protrusion pattern 52a is formed using the above-described equations (11) and (12) in such a manner that the receptor forming region 31 in which the forming region-side recess/protrusion pattern 52a is formed has lyophilicity for the solution.

Note that, in the first embodiment, a case where the forming region-side recess/protrusion pattern 52a is formed with the pitch p between protruding portions adjacent to each other, the outer diameter D of protruding portions, and the height H of protruding portions set to 3 μm, 2 μm, and 0.05 μm, respectively, will be described as an example. This configuration enables the lyophilicity of the receptor forming region 31 to be improved in the first embodiment.

In addition, the pitch p, the outer diameter D of protruding portions, the height H of protruding portions of the forming region-side recess/protrusion pattern 52a are set to values matching physical properties of the receptor 30 (physical properties of the solution forming the receptor 30). That is, the forming region-side recess/protrusion pattern 52a is formed in a shape matching the physical properties of the receptor 30.

It has been known that a pattern formed by a plurality of protruding portions the pitch, height, and outer diameter of which are set in accordance with the above-described relationships exhibits lyophilicity. This is a phenomenon of an increase in surface roughness, which is expressed by the well-known Wenzel equation (the equation (13) below), causing lyophilicity to be improved, which has been explained in a physical sense.

[Math. 13]

cos θ_{w}=τ_{rough} cos θ_{eg} (13)

Consequently, the forming region-side recess/protrusion pattern 52a is a pattern having a degree of roughness that allows the solution forming the receptor 30 to be present in gaps formed by a plurality of protruding portions or a plurality of recessed portions that form the forming region-side recess/protrusion pattern 52a.

The reason why the forming region-side recess/protrusion pattern 52a is formed with such a pattern is that, when depth of the plurality of protruding portions or the plurality of recessed portions that form the forming region-side recess/protrusion pattern 52a is sufficiently small compared with the size of droplets of the solution, it becomes possible for the solution to cover the wholes of the plurality of protruding portions or the plurality of recessed portions. The reason is also that, since the solution covering the wholes of the plurality of protruding portions or the plurality of recessed portions enables the forming region-side recess/protrusion pattern 52a to be considered as a single plane, the above-described Wanzel equation holds.

### (Exterior Region-Side Recess/Protrusion Pattern)

The exterior region-side recess/protrusion pattern 52b is formed in the exterior region 32 within the front surface of the membrane 22.

In addition, the exterior region-side recess/protrusion pattern 52b is, as with the forming region-side recess/protrusion pattern 52a, formed with a pattern in which a plurality of protruding portions or a plurality of recessed portions are consecutively repeated. In the first embodiment, a case where each protruding portion and each recessed portion are formed in a circle pillar shape and a round opening, respectively, will be described as an example. Note that each protruding portion may be formed in, for example, a square pillar shape or a pyramid shape. In addition, each recessed portion may be formed in, for example, a polygonal opening or a groove.

In the first embodiment, a case where the exterior region-side recess/protrusion pattern 52b is formed by a plurality of recessed portions (holes) will be described as an example.

In addition, in the first embodiment, a case where each of the recessed portions forming the exterior region-side recess/protrusion pattern 52b is formed in a circle when viewed from the thickness direction of the membrane 22 will be described as an example. Note that the “circle” in which each of the recessed portions forming the exterior region-side recess/protrusion pattern 52b is formed is not limited to a perfect circle and may be a round shape other than a perfect circle, such as an ellipse.

As illustrated in FIG. 7, a cross-section of the exterior region-side recess/protrusion pattern 52b is a shape in which recessed portions are arranged. The depth of grooves that the exterior region-side recess/protrusion pattern 52b forms is a depth that does not allow the grooves to penetrate through the membrane 22 in the thickness direction. It has been known that the surface of a pattern formed in a shape in which recessed portions are arranged in this manner has lyophobicity, and this property is generally referred to as the lotus effect. This is a phenomenon that has been explained in a physical sense by the well-known Cassie's formula.

In addition, the exterior region-side recess/protrusion pattern 52b is formed using the above-described equations (11) and (12) in such a manner that the exterior region 32, in which the exterior region-side recess/protrusion pattern 52b is formed, has lyophobicity against the solution.

In the first embodiment, a case where the exterior region-side recess/protrusion pattern 52b is formed with pitch between recessed portions adjacent to each other, inner diameter of recessed portions, and depth of recessed portions set to 1 μm, 1 μm, and 1 μm, respectively, will be described as an example. Note that the depth of the recessed portions is set to, for example, a value within a range of 1 μm or more and 1.5 μm or less.

In addition, the pitch, the inner diameter of the recessed portions, the depth of the recessed portions of the exterior region-side recess/protrusion pattern 52b are set to values matching physical properties of the receptor 30 (physical properties of the solution forming the receptor 30). That is, the exterior region-side recess/protrusion pattern 52b is formed in a shape matching the physical properties of the receptor 30.

Note that, in FIG. 7, a cross-section of the exterior region-side recess/protrusion pattern 52b is illustrated as a configuration in which a plurality of grooves are formed by illustrating only a cross-sectional view of a portion taken along the line VII-VII in FIG. 2 among the cross-sections of the exterior region-side recess/protrusion pattern 52b for the purpose of clarity. However, an actual structure of the exterior region-side recess/protrusion pattern 52b is a structure in which a plurality of recessed portions are arranged at intervals in an array.

In addition, although the lotus effect manifests itself on the exterior region-side recess/protrusion pattern 52b regardless of whether the exterior region-side recess/protrusion pattern 52b is formed using protruding portions or recessed portions, a larger effect in general manifests itself on a pattern having more cavity portions. For this reason, the exterior region-side recess/protrusion pattern 52b formed using protruding portions has more intense lyophobicity than a case where the exterior region-side recess/protrusion pattern 52b is formed using recessed portions.

Therefore, the exterior region-side recess/protrusion pattern 52b is a pattern having a degree of roughness that enables the solution forming the receptor 30 to be prevented from infiltrating into gaps formed by a plurality of protruding portions or a plurality of recessed portions that form the exterior region-side recess/protrusion pattern 52b.

The reason why the exterior region-side recess/protrusion pattern 52b is formed with such a pattern is that, when the depth of the plurality of protruding portions or the plurality of recessed portions that form the exterior region-side recess/protrusion pattern 52b is sufficiently large compared with the size of droplets of the solution, the solution does not infiltrate into the gaps formed by the plurality of protruding portions or the plurality of recessed portions. The reason is also that, since the solution not infiltrating into the gaps formed by the plurality of protruding portions or the plurality of recessed portions enables the exterior region-side recess/protrusion pattern 52b to be considered as a composite plane, the well-known Cassie-Baxter equation holding causes the solution to be repelled due to the above-described Lotus effect.

Consequently, the forming region-side recess/protrusion pattern 52a is formed with a pattern that causes the degree of roughness of the receptor forming region 31 to be lower than the degree of roughness of the exterior region 32. In addition to the above, the exterior region-side recess/protrusion pattern 52b is formed with a pattern that causes the degree of roughness of the exterior region 32 to be higher than the degree of roughness of the receptor forming region 31. That is, the degree of roughness of the forming region-side recess/protrusion pattern 52a is lower than the degree of roughness of the exterior region-side recess/protrusion pattern 52b.

Therefore, the forming region-side recess/protrusion pattern 52a is a pattern that causes the lyophilicity of the receptor forming region 31 to be higher than the lyophilicity of the exterior region 32.

As described above, the receptor 30 is formed by applying a PEI solution or the like to a vicinity of the center of the membrane 22, using inkjet-spotting or the like.

Thus, since the oxide film SO formed at the outermost layer of the membrane 22 has high wettability, the PEI solution applied to the front surface of the membrane 22 is distributed on the front surface of the membrane 22 with good adhesion.

In addition to the above, the PEI solution applied to the front surface of the membrane 22 efficiently spreads inside the receptor forming region 31 due to high wettability that the oxide film SO has and lyophilicity that the forming region-side recess/protrusion pattern 52a has.

On the other hand, the high wettability that the oxide film SO has and the lyophilicity that the forming region-side recess/protrusion pattern 52a has make the PEI solution applied to the front surface of the membrane 22 more likely to flow out toward the outer periphery of the membrane 22. However, the PEI solution flowing toward the outer periphery of the membrane 22 is blocked from flowing out by lyophobicity that the exterior region-side recess/protrusion pattern 52b has. Because of this effect, it becomes possible to efficiently apply the receptor 30 to the receptor forming region 31.

### (Verification and Examination of Lyophilicity)

Hereinafter, using FIGS. 12 and 13, a result of verification and examination of lyophilicity that the receptor forming region 31 in which the forming region-side recess/protrusion pattern 52a is formed has will be described.

For the verification and examination of lyophilicity, a sample membrane and a comparison target membrane were used.

On the sample membrane, the forming region-side recess/protrusion pattern 52a that is a pattern in which a plurality of protruding portions (pillars) are consecutively repeated was formed in the receptor forming region 31, as illustrated in FIGS. 12 and 13. In addition to the above, on the sample membrane, the exterior region-side recess/protrusion pattern 52b that is a pattern in which a plurality of recessed portions (holes) are consecutively repeated was formed in the exterior region 32, as illustrated in FIGS. 12 and 13.

Note that the outer diameter of the protruding portions was set to 2 μm, the inner diameter of the recessed portions was set to 1 μm, and the height of the protruding portions and the depth of the recessed portions were set to 50 μm.

On the comparison target membrane, the forming region-side recess/protrusion pattern 52a was not formed in the receptor forming region 31, and the receptor forming region 31 was formed by a uniform plane having the same height as the outer edges of the recessed portions forming the exterior region-side recess/protrusion pattern 52b.

When two drops of the solution were applied to the receptor forming region 31 of each of the sample membrane and the comparison target membrane only once, it was confirmed that the solution spread to a larger area on the sample membrane than on the comparison target membrane.

(Relationship between Contact Angle R and Forming Region-Side Recess/Protrusion Pattern 52a)

A relationship between the contact angle R and the forming region-side recess/protrusion pattern 52a is defined such that, when the forming region-side recess/protrusion pattern 52a is formed by a plurality of protruding portions, the contact angle R is, for example, set to be half (10° or less) with respect to the flat plane (bottom surface) of the forming region-side recess/protrusion pattern 52a. On the other hand, when the forming region-side recess/protrusion pattern 52a is formed by a plurality of recessed portions, the contact angle R is, for example, set to be within a range of two times or more and two and a half times or less (40° or more) with respect to the flat plane (outer edge surface) of the forming region-side recess/protrusion pattern 52a.

### (Variations of Membrane, Forming Region-Side Recess/Protrusion Pattern, and Exterior Region-Side Recess/Protrusion Pattern)

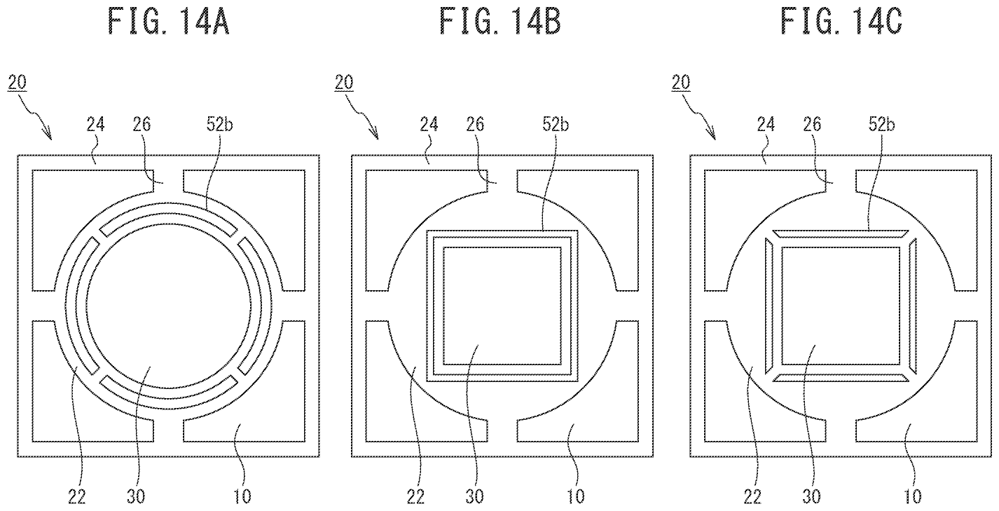

Therefore, variations of the configurations of the membrane 22 and the exterior region-side recess/protrusion pattern 52b include, for example, configurations illustrated in FIGS. 14A to 16C.

That is, as illustrated in FIG. 14A, the exterior region-side recess/protrusion pattern 52b may have a configuration in which the exterior region-side recess/protrusion pattern 52b has discontinuities at some portions thereof instead of being arranged over the entire circumference, or, as illustrated in FIG. 14B, the exterior region-side recess/protrusion pattern 52b may be arranged in a quadrilateral. In addition, as illustrated in FIG. 14C, the exterior region-side recess/protrusion pattern 52b may have a configuration in which discontinuities are disposed at some portions of the exterior region-side recess/protrusion pattern 52b arranged in a quadrilateral.

The configuration including discontinuities at some portions of the exterior region-side recess/protrusion pattern 52b can be applied to, for example, a case where the exterior region-side recess/protrusion pattern 52b does not necessarily have to be arranged over the entire circumference depending on viscosity of the PEI solution forming the receptor 30. Note that, in the configuration including discontinuities at some portions of the exterior region-side recess/protrusion pattern 52b, the exterior region-side recess/protrusion pattern 52b appears to have discontinuities from a macroscopic perspective because intervals between protruding portions or recessed portions adjacent to each other at the portions having discontinuities are sufficiently large compared with those at portions not having discontinuities.

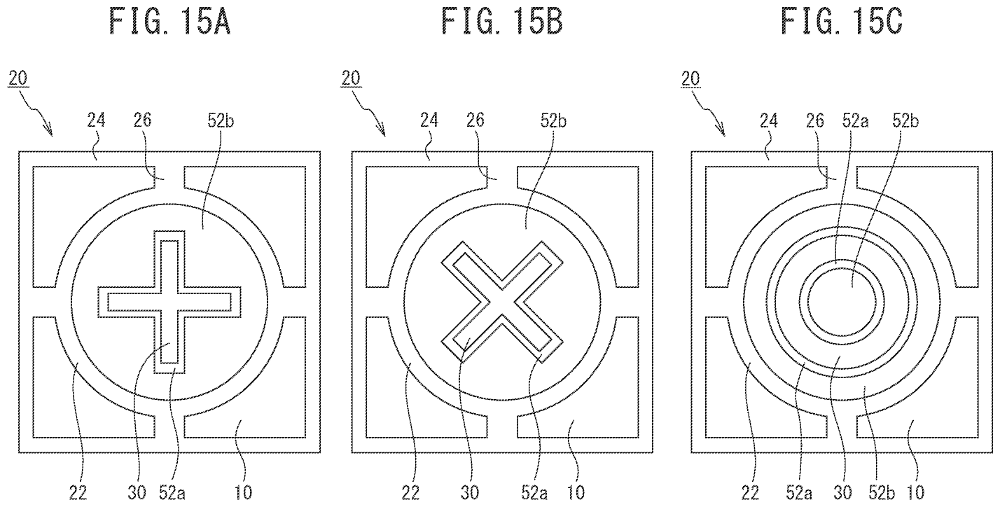

In addition, as illustrated in FIGS. 15A to 15C, it may be configured such that the receptor 30 is formed in a specific shape by devising the shapes of the forming region-side recess/protrusion pattern 52a and the exterior region-side recess/protrusion pattern 52b.

For example, as illustrated in FIG. 15A, the forming region-side recess/protrusion pattern 52a may be formed in a shape that has a cross-shaped region including a central portion of the membrane 22. In addition to the above, the exterior region-side recess/protrusion pattern 52b may be formed in a circular shape the outer periphery of which extends along the outer periphery of the membrane 22. In FIG. 15A, an example in which the end portions of the cross shape are formed pointing to vicinities of the four coupling portions 26 is illustrated. In this case, the receptor 30 is formed in, for example, a cross shape on a cross-shaped receptor forming region 31 in which the forming region-side recess/protrusion pattern 52a is formed. Thus, it becomes possible to selectively form the receptor 30 in vicinities of the coupling portions 26, in which flexible resistors 50a to 50d are formed, and it thereby becomes possible to efficiently transmit bending of the membrane 22 to the flexible resistors 50. Because of this effect, it is also possible to reduce the amount of the receptor 30 to be applied.

In addition, as illustrated in FIG. 15B, an example in which the end portions of a cross shape are formed pointing to circular-arc-shaped outer peripheries that the membrane 22 has between the four coupling portions 26 is illustrated. In this case, the receptor 30 is formed in, for example, a cross shape on a cross-shaped receptor forming region 31 in which the forming region-side recess/protrusion pattern 52a is formed. When the forming region-side recess/protrusion pattern 52a and the exterior region-side recess/protrusion pattern 52b illustrated in FIG. 15B are formed, it becomes possible to selectively form the receptor 30 in a region away from the coupling portions 26, in which the flexible resistors 50a to 50d are formed. This configuration enables variation in the sensitivity of the surface stress sensor 1 to be reduced.

In addition, as illustrated in FIG. 15C, an annular forming region-side recess/protrusion pattern 52a may be formed. In addition to the above, by forming an annular exterior region-side recess/protrusion pattern 52b on the outer side of the forming region-side recess/protrusion pattern 52a, a circular exterior region-side recess/protrusion pattern 52b may be formed in a region including the center of the membrane 22. In the case of FIG. 15C, the receptor 30 is formed on an annular receptor forming region 31 in which the forming region-side recess/protrusion pattern 52a is formed. When the forming region-side recess/protrusion pattern 52a and the exterior region-side recess/protrusion pattern 52b illustrated in FIG. 15C are formed, it becomes possible to selectively form the receptor 30 in the vicinities of the coupling portions 26, in which the flexible resistors 50a to 50d are formed. This configuration enables detection precision of the surface stress sensor 1 to be improved. In addition to the above, this configuration enables variation in the detection precision to be reduced.

Note that the exterior region-side recess/protrusion pattern 52b has a circular shape the outer periphery of which extends along the outer periphery of the membrane 22 and the shape of the receptor forming region 31, in which the forming region-side recess/protrusion pattern 52a is formed on a central portion of the membrane 22, is not limited to the shapes described above. In addition, as the shape of the receptor forming region 31, any shape may be chosen from among, for example, a polygonal shape, a shape extending from the center of the membrane 22 toward the outer periphery in a radial manner, and the like as long as the shape enables the sensor sensitivity of the surface stress sensor 1 to be maintained at a sufficient level.

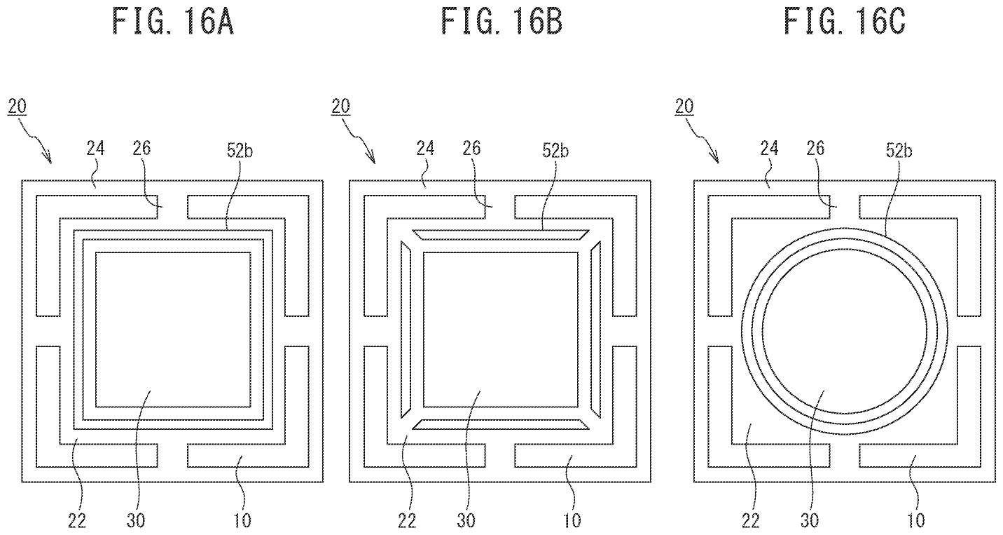

In addition, as illustrated in FIGS. 16A to 16C, the shape of the membrane 22 may be set to a quadrilateral. In this case, as illustrated in FIG. 16A, the exterior region-side recess/protrusion pattern 52b may be arranged in a quadrilateral, or, as illustrated in FIG. 16B, the exterior region-side recess/protrusion pattern 52b may have a configuration in which discontinuities are disposed at some portions of the exterior region-side recess/protrusion pattern 52b arranged in a quadrilateral. In addition, as illustrated in FIG. 16C, the exterior region-side recess/protrusion pattern 52b may be arranged over the entire circumference in a concentric manner. Note that, although not particularly illustrated, the exterior region-side recess/protrusion pattern 52b as illustrated in FIG. 16C may have a configuration in which discontinuities are disposed at some portions of the exterior region-side recess/protrusion pattern 52b.

When a configuration in which discontinuities are disposed at some portions of the exterior region-side recess/protrusion pattern 52b is employed, it is suitable that the positions of the discontinuities be not arranged at positions between the center of the membrane 22 and the coupling portions 26, as illustrated in FIGS. 14A, 14C, and 16B. This configuration enables a possibility of the PEI solution, which forms the receptor 30, coming into contact with the flexible resistors 50 to be reduced even when, for example, the PEI solution flows out through the discontinuities.

In addition, as illustrated in FIGS. 14B, 14C, 16A, and 16B, the shape of the receptor 30 may be set to a quadrilateral.

Note that FIGS. 14A to 16C illustrate states in which, when viewed from the thickness direction of the membrane 22, the support base member 10 arranged under the detection base member 20 is visible through regions that serve as cavity portions surrounded by the membrane 22, the holding member 24, and the coupling portions 26.

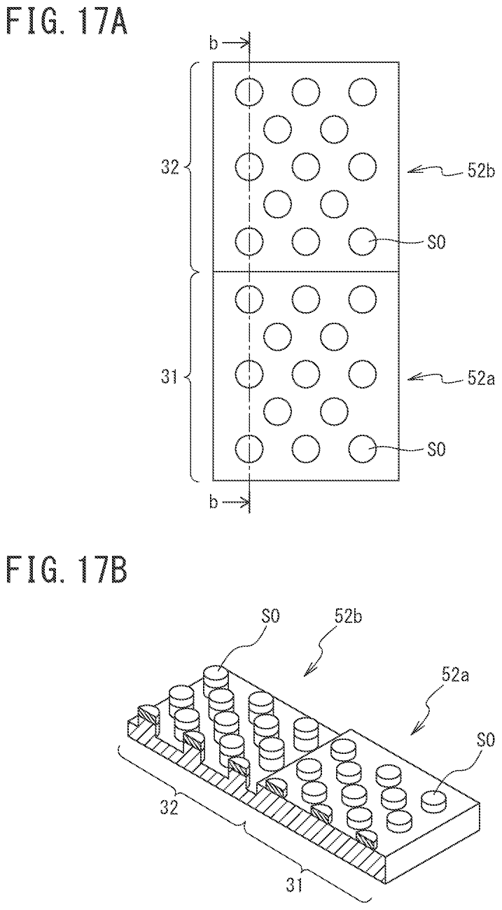

In addition, the exterior region-side recess/protrusion pattern 52b may be formed by a plurality of protruding portions, as illustrated in FIGS. 17A and 17B, provided that the exterior region-side recess/protrusion pattern 52b is a pattern that causes the degree of roughness of the exterior region 32 to be higher than the degree of roughness of the receptor forming region 31. In this case, as illustrated in FIG. 17B, the protruding portions forming the exterior region-side recess/protrusion pattern 52b are set to be taller than the protruding portions forming the forming region-side recess/protrusion pattern 52a.

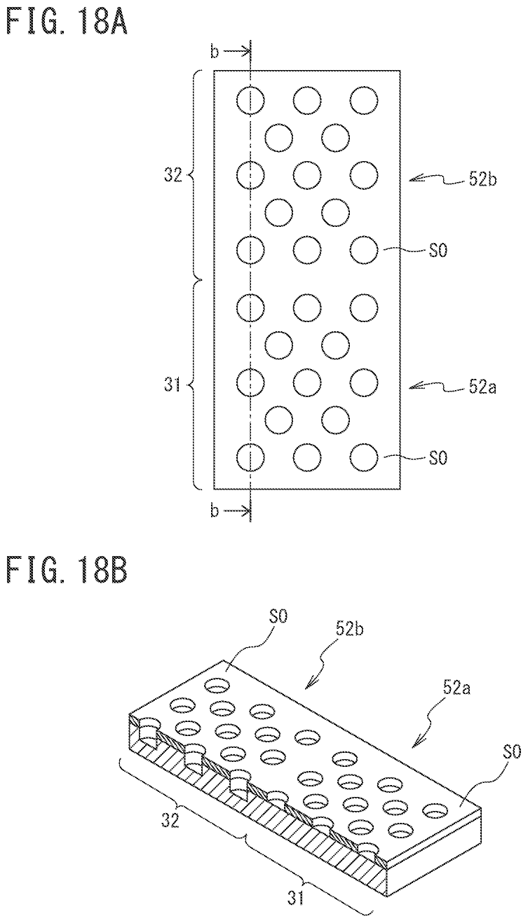

In addition, when the forming region-side recess/protrusion pattern 52a is formed by a plurality of recessed portions, the exterior region-side recess/protrusion pattern 52b may be formed by a plurality of recessed portions, as illustrated in FIGS. 18A and 18B, provided that the exterior region-side recess/protrusion pattern 52b is a pattern that causes the degree of roughness of the exterior region 32 to be higher than the degree of roughness of the receptor forming region 31. In this case, as illustrated in FIG. 18B, the recessed portions forming the exterior region-side recess/protrusion pattern 52b are set to be deeper than the recessed portions forming the forming region-side recess/protrusion pattern 52a.

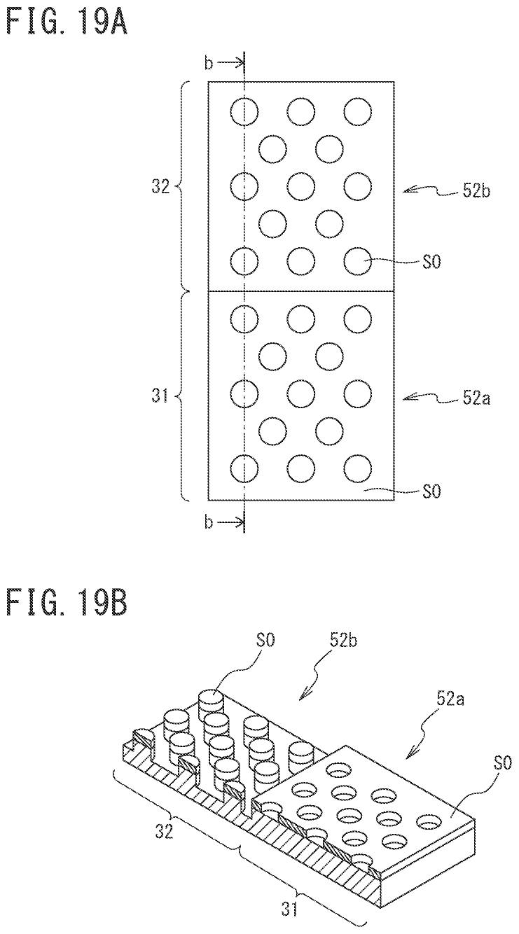

In addition, when the forming region-side recess/protrusion pattern 52a is formed by a plurality of recessed portions, the exterior region-side recess/protrusion pattern 52b may be formed by a plurality of protruding portions, as illustrated in FIGS. 19A and 19B, provided that the exterior region-side recess/protrusion pattern 52b is a pattern that causes the degree of roughness of the exterior region 32 to be higher than the degree of roughness of the receptor forming region 31. In this case, as illustrated in FIG. 19B, the height of the protruding portions forming the exterior region-side recess/protrusion pattern 52b is set to be greater than the depth of the recessed portions forming the forming region-side recess/protrusion pattern 52a.

Note that the forming region-side recess/protrusion pattern 52a and the exterior region-side recess/protrusion pattern 52b described in the first embodiment have a configuration in which the front surface of the membrane 22 is covered with the oxide film SO and the membrane 22 has high wettability for the receptor 30, which is formed of a hydrophilic solution. Note that the hydrophilic solution is a solvent compatible with water, such as alcohols including ethanol, isopropanol, and propylene glycol monomethyl ether, acetone, and DMF.

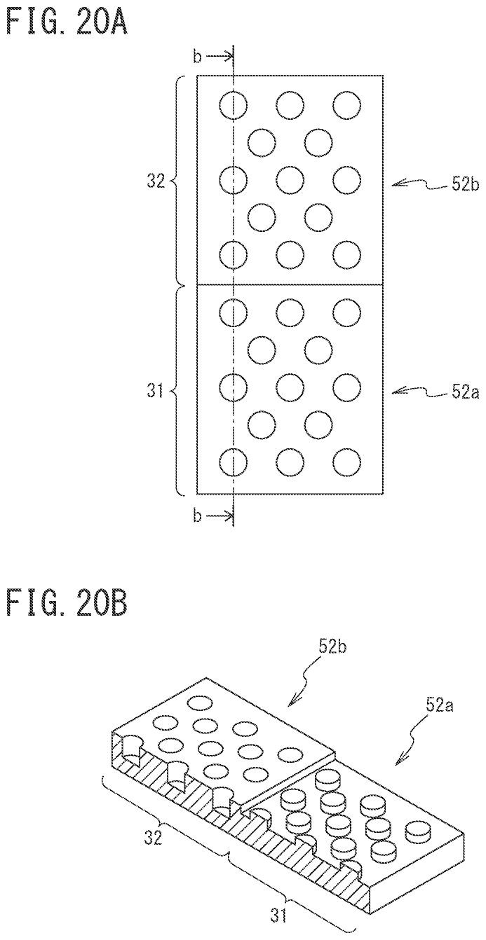

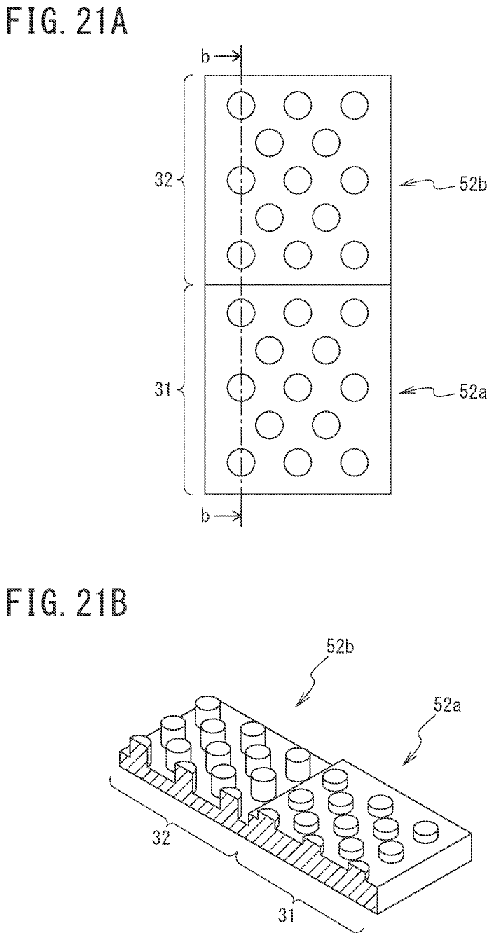

However, when the receptor 30 is formed of a hydrophobic solution (for example, 1,1,2,2-tetrachloroethane, dichloromethane, toluene, hexane, or the like), silicon, for example, has a higher wettability than the oxide film SO. Thus, it is preferable that silicon be exposed on the front surface of the membrane 22, as illustrated in FIGS. 20A to 23B. Note that FIGS. 20A and 20B illustrate a configuration in which silicon is exposed without the forming region-side recess/protrusion pattern 52a and the exterior region-side recess/protrusion pattern 52b being covered by an oxide film, unlike the configuration illustrated in FIG. 8. Likewise, FIGS. 21A to 23B illustrate configurations in which silicon is exposed without the forming region-side recess/protrusion pattern 52a and the exterior region-side recess/protrusion pattern 52b being covered by an oxide film, unlike the configurations illustrated in FIGS. 17A to 19B, respectively.

### (Support Base Member)

The support base member 10 is arranged on the one surface of the package substrate 2 and is attached to the package substrate 2 with the connecting portion 4 interposed therebetween.

In the first embodiment, a case where the center of the support base member 10 overlaps a position at which the connecting portion 4 is arranged will be described as an example.

Area of the support base member 10 (in FIG. 1, area of the support base member 10 when the support base member 10 is viewed from the vertical direction) is larger than area of the connecting portion 4.

Thickness of the support base member 10 (in FIG. 1, length in the vertical direction of the support base member 10) is set to 80 μm or more. Note that the thickness of the support base member 10 may be set to a value within a range of 80 μm or more and 750 μm or less.

As a material of which the support base member 10 is formed, for example, a material containing any one of silicon (Si), sapphire, gallium arsenide, glass, and quartz can be used.

In the first embodiment, a case where silicon is used as a material of which the support base member 10 is formed will be described as an example.

Because of this configuration, the value of the linear expansion coefficient of the support base member 10 is set to 5.0×10⁻⁶/° C. or less in the first embodiment.

Values of linear expansion coefficients of materials that can be used as a material of which the support base member 10 is formed will be described below.

A value of a linear expansion coefficient of silicon is 3.9×10⁻⁶/° C. or less in an environment with a temperature of a normal temperature or higher and 1000° C. or lower.

A value of a linear expansion coefficient of sapphire is 9.0×10⁻⁶/° C. or less in an environment with a temperature of 0° C. or higher and 1000° C. or lower.

A value of a linear expansion coefficient of gallium arsenide (GaAs) is 6.0×10⁻⁶/° C. or less in an environment with a temperature of 0 K or higher and 300 K or lower.

A value of a linear expansion coefficient of glass (float glass) is 8.5×10⁻⁶/° C. or less to 9.0×10⁻⁶/° C. or less in an environment with a temperature of 0° C. or higher and 300° C. or lower.

A value of a linear expansion coefficient of quartz is 0.59×10⁻⁶/° C. or less in an environment with a temperature of 0° C. or higher and 300° C. or lower. Note that the value of the linear expansion coefficient of quartz has a peak at around 300° C.

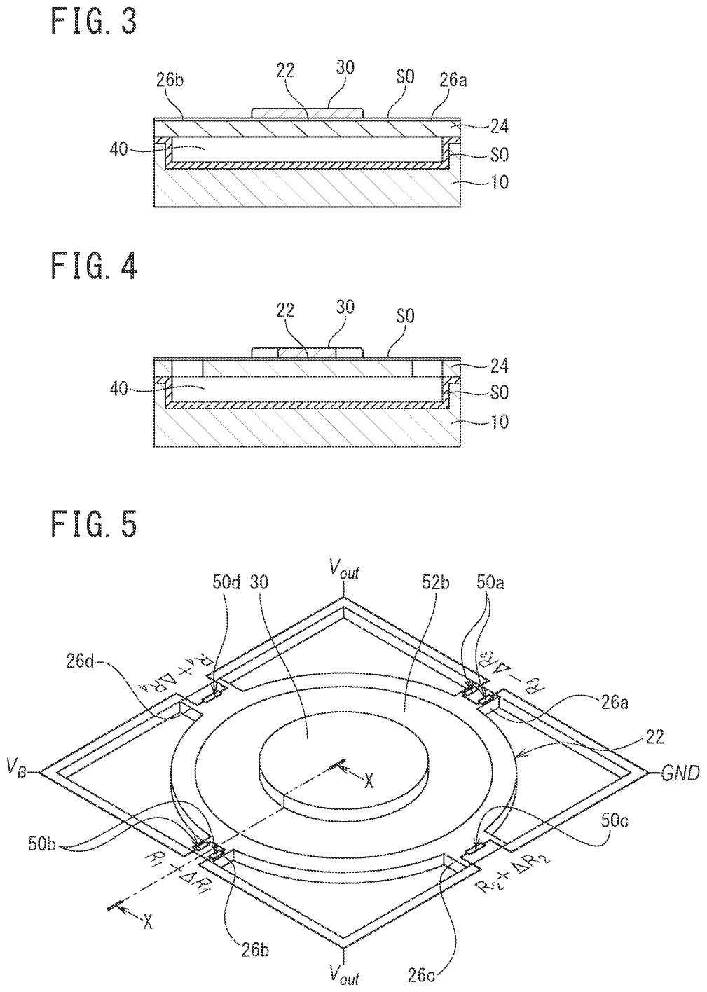

In addition, on surfaces of the support base member 10 that face the detection base member 20 and surfaces of the support base member 10 that face the cavity portion 40, an oxide film SO is formed, as illustrated in FIGS. 3 and 4.

### (Method for Manufacturing Surface Stress Sensor)

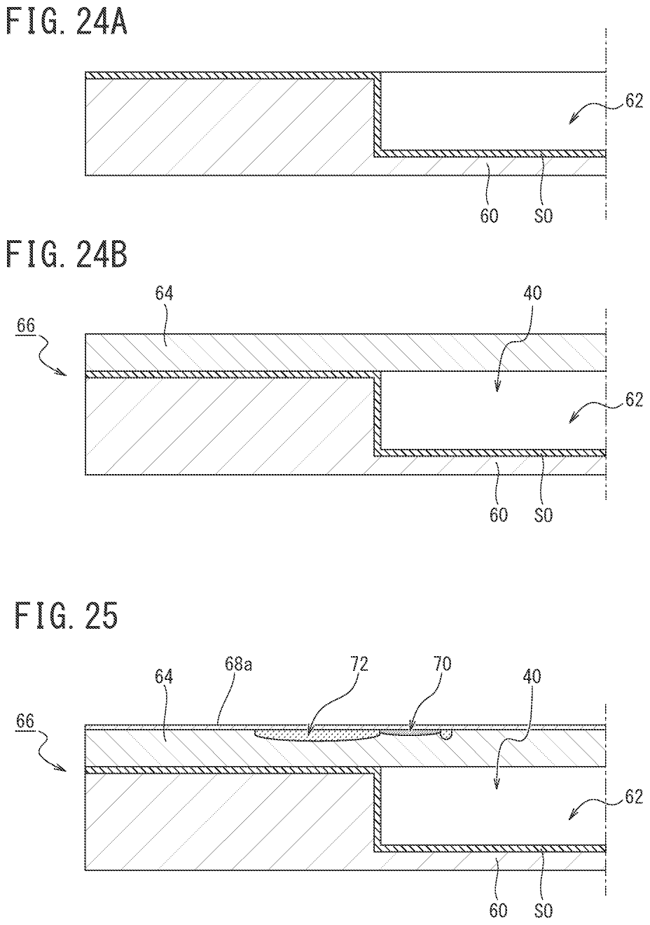

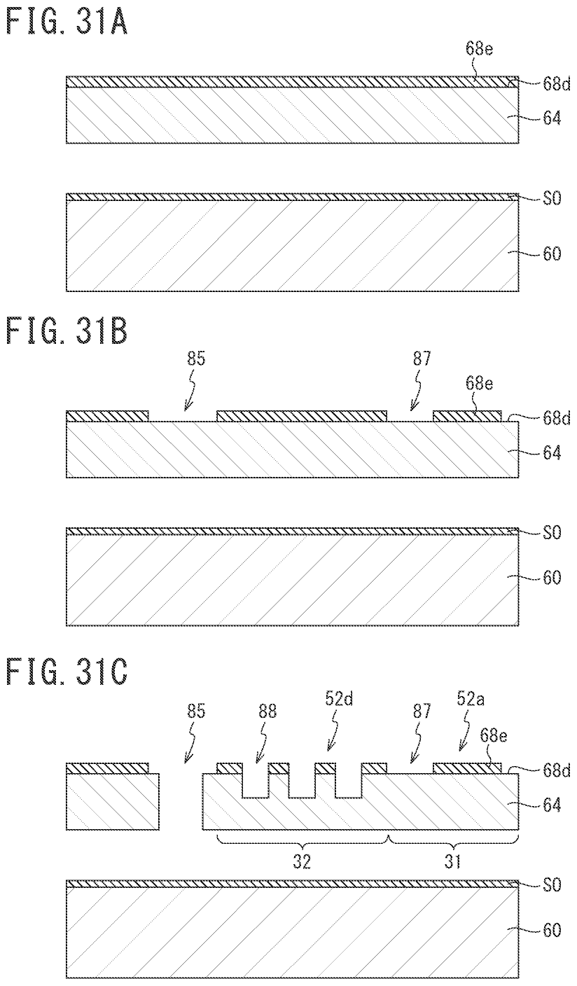

Using FIGS. 24A to 31C while referring to FIGS. 1 to 23, a method for manufacturing the surface stress sensor 1 will be described. Note that cross-sectional views in FIGS. 24A to 30B correspond to a cross-sectional view taken along the line X-X in FIG. 5. In addition, cross-sectional views in FIGS. 31A to 31C correspond to a cross-sectional view taken along the line X-Y in FIG. 2.

The method for manufacturing the surface stress sensor 1 includes a stacked body formation step, a first ion implantation step, a second ion implantation step, a heat treatment step, a wiring layer formation step, and an oxide film formation step. In addition to the above, the method for manufacturing the surface stress sensor 1 includes a forming region-side recess/protrusion pattern formation step, an exterior region-side recess/protrusion pattern formation step, a removal step, and a receptor formation step.

### (Stacked Body Formation Step)

In the stacked body formation step, first, a recessed portion 62 (trench) is formed on one surface of a first silicon substrate 60 that serves as a material of the support base member 10, using lithography and etching technologies, as illustrated in FIG. 24A. Depth of the recessed portion 62 is set to, for example, 7 μm. Subsequently, an oxide film SO (silicon oxide film) is formed on the one surface of the first silicon substrate 60 including the recessed portion 62 by thermal oxidation. Depth of the oxide film SO is set to, for example, 1 μm.

Next, by sticking a second silicon substrate 64 that serves as a material of the detection base member 20 to the first silicon substrate 60, on which the recessed portion 62 and the oxide film SO are formed, using one of various types of joining technology, such as adhesion, a stacked body 66 (cavity wafer) is formed, as illustrated in FIG. 24B.

By performing the stacked body formation step as described above, the cavity portion 40 the top, bottom, left, and right sides of which are enclosed by silicon (the first silicon substrate 60 and the second silicon substrate 64) is formed at a predetermined position in the stacked body 66.

Consequently, in the stacked body formation step, by forming the recessed portion 62 on the one surface of the support base member 10 and further sticking the detection base member 20 to the support base member 10 in such a way that the detection base member 20 covers the recessed portion 62, the stacked body 66 in which the cavity portion 40 is formed between the support base member 10 and the detection base member 20 is formed.

### (First Ion Implantation Step)

In the first ion implantation step, first, a surface on the upper side of the second silicon substrate 64 is oxidized and a first silicon oxide film 68a is thereby formed, and first ions are selectively implanted into flexible resistor regions 70, using a photoresist pattern (not illustrated), as illustrated in FIG. 25.

Consequently, in the first ion implantation step, the first ions are implanted into selected partial regions (the flexible resistor regions 70) on the outer side of a preset region including the center of the detection base member 20 within a surface of the detection base member 20 on the opposite side to a surface thereof facing the support base member 10.

### (Second Ion Implantation Step)

In the second ion implantation step, the photoresist used in the first ion implantation step is removed, a photoresist pattern (not illustrated) different from the photoresist pattern used in the first ion implantation step is further formed, and second ions are implanted into low resistance regions 72, as illustrated in FIG. 25.

Consequently, in the second ion implantation step, the second ions are implanted into selected regions on the outer side of the regions (the flexible resistor regions 70) into which the first ions were implanted on the detection base member 20.

### (Heat Treatment Step)

In the heat treatment step, the photoresist used in the second ion implantation step is removed, and, further, the stacked body 66 is subjected to heat treatment (annealing treatment) with the aim of activation of the first ions and the second ions. After the stacked body 66 has been subjected to the heat treatment, the first silicon oxide film 68a is removed.

Consequently, in the heat treatment step, by subjecting the stacked body 66 into which the first ions and the second ions were implanted to heat treatment, the flexible resistor regions 70 are formed in the regions into which the first ions were implanted and the low resistance regions 72 are also formed in the regions into which the second ions were implanted.

### (Wiring Layer Formation Step and Oxide Film Formation Step)

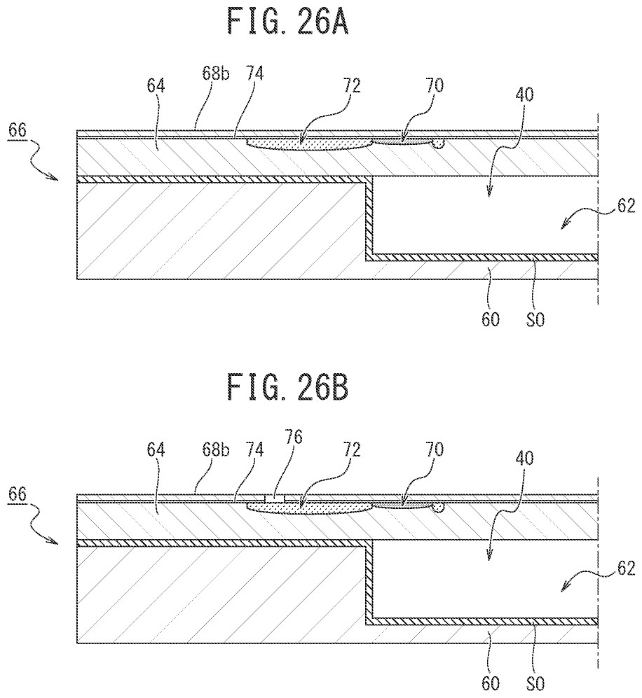

In the wiring layer formation step, a silicon nitride film 74 and a second silicon oxide film 68b are stacked in this order on a surface on the upper side of the second silicon substrate 64, as illustrated in FIG. 26A. By means of regular lithography and oxide film etching, holes 76 are formed in the second silicon oxide film 68b and the silicon nitride film 74, as illustrated in FIG. 26B.

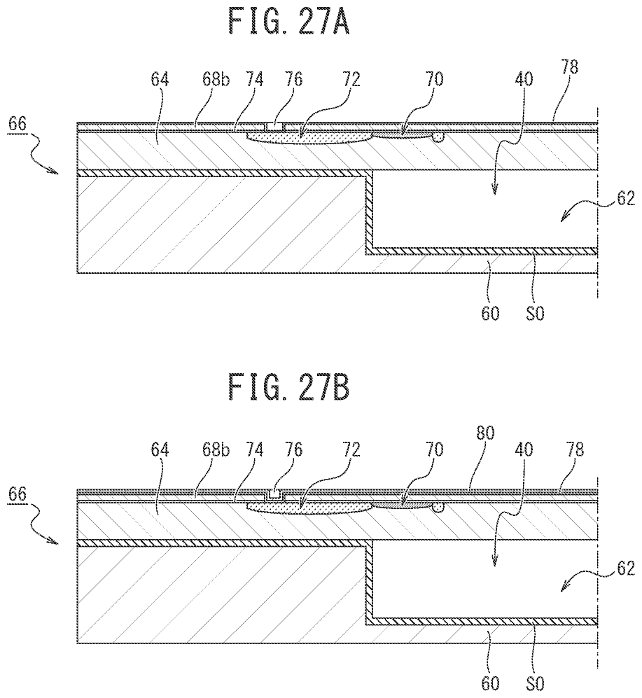

Next, as illustrated in FIG. 27A, a laminated film 78 formed of Ti and TiN is formed on the second silicon oxide film 68b by sputtering and the stacked body 66 is subjected to heat treatment. The laminated film 78 is a so-called barrier metal that plays a role of preventing a metal film, such as an Al film, from anomalously diffusing into Si, and performing heat treatment causes interfaces between Si and Ti, which exist on the bottoms of the holes 76, to be silicided and it becomes possible to form connections with low resistance.

Further, as illustrated in FIG. 27B, a metal film 80, such as an Al film, is stacked on the laminated film 78 by sputtering.

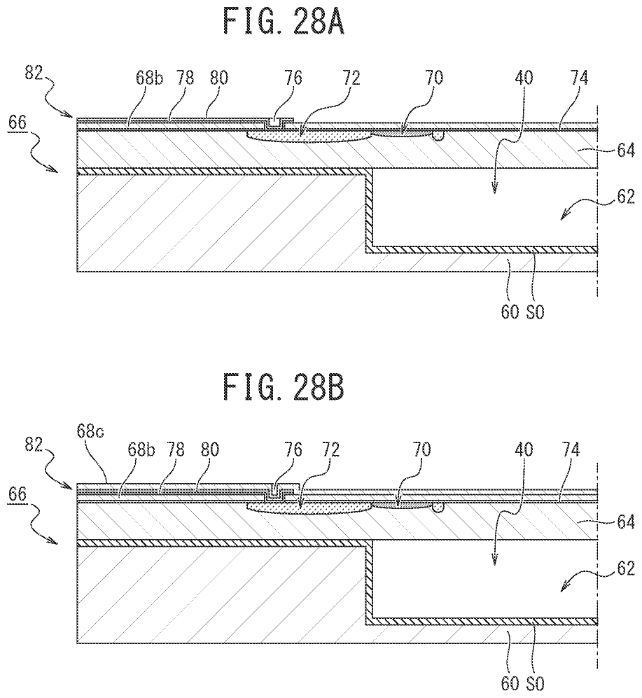

Next, by patterning the metal film 80 using photolithography and etching technologies, a wiring layer 82 as illustrated in FIG. 28A is formed. Further, as illustrated in FIG. 28B, a third silicon oxide film 68c is stacked as an insulating layer.

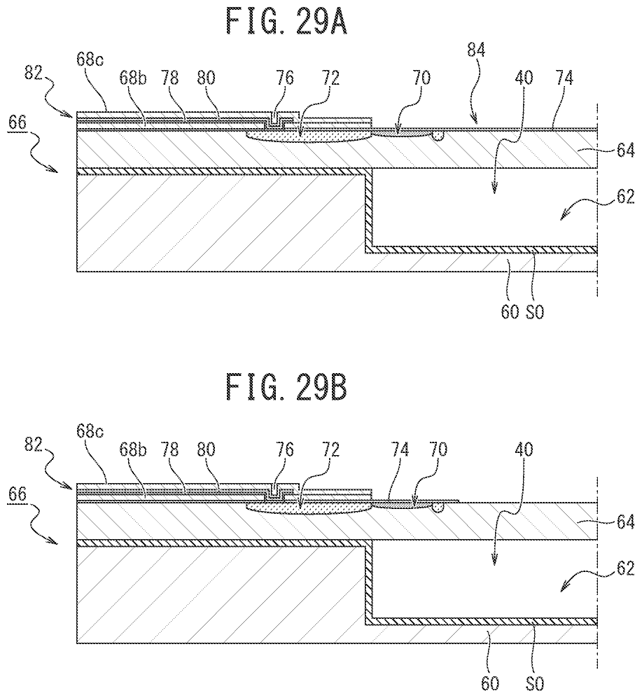

Subsequently, as illustrated in FIG. 29A, a photoresist pattern (not illustrated) that covers a region excluding the flexible resistor regions 70 and a membrane setting region 84 that is a preset region including the center of the detection base member (a region that is to serve as the membrane later) is formed. Further, by means of an etching technology, portions of the third silicon oxide film 68c and the second silicon oxide film 68b that are formed in the flexible resistor regions 70 and the membrane setting region 84 are removed. A photoresist pattern (not illustrated) that covers a region excluding the membrane setting region 84 is formed, and, as illustrated in FIG. 29B, a portion of the silicon nitride film 74 in the membrane setting region 84 is removed.

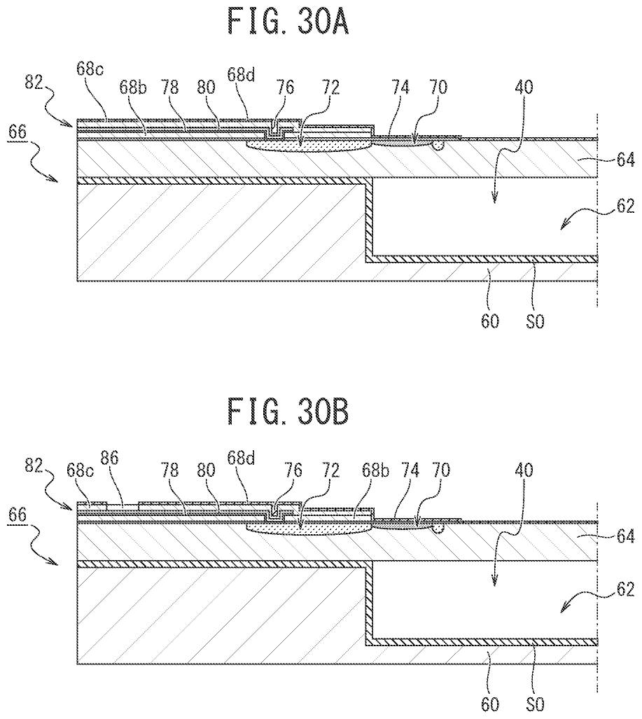

Subsequently, as the oxide film formation step, a fourth silicon oxide film 68d is stacked on the third silicon oxide film 68c, the flexible resistor regions 70, and the membrane setting region 84, as illustrated in FIG. 30A.

In the oxide film formation step, the oxide film is formed on the receptor forming region 31 and the exterior region 32. Note that the oxide film may be formed only on either a region in which the receptor forming region 31 is to be formed or a region in which the exterior region 32 is to be formed.

Next, as illustrated in FIG. 30B, PADs 86 for acquiring outputs from the flexible resistors 50 are formed by means of regular photolithography and etching technologies.

Consequently, in the wiring layer formation step, the wiring layer 82 that is electrically connected to the flexible resistors 50 is formed.

### (Forming Region-Side Recess/Protrusion Pattern Formation Step, Exterior Region-Side Recess/Protrusion Pattern Formation Step, and Removal Step)

In the forming region-side recess/protrusion pattern formation step, the forming region-side recess/protrusion pattern 52a is formed in the receptor forming region 31.

In the exterior region-side recess/protrusion pattern formation step, the exterior region-side recess/protrusion pattern 52b is formed in the exterior region 32.

In the removal step, by cutting off portions of the membrane setting region 84 by etching, the four coupling portions 26a to 26d constituting two pairs are patterned.

In the first embodiment, a case where the forming region-side recess/protrusion pattern formation step, the exterior region-side recess/protrusion pattern formation step, and the removal step are performed at the same time will be described as an example.

Hereinafter, details of the forming region-side recess/protrusion pattern formation step, the exterior region-side recess/protrusion pattern formation step, and the removal step will be described using FIGS. 31A to 31C while referring to FIGS. 24A, 24B, 30A and 30B. Note that, in FIGS. 31A to 31C, illustration of, among the constituent elements illustrated in FIGS. 24A to 30B, constituent elements other than the first silicon substrate 60, the second silicon substrate 64, and the fourth silicon oxide film 68d is omitted for the purpose of clarity.

First, as illustrated in FIG. 31A, a fifth silicon oxide film 68e is further stacked on the fourth silicon oxide film 68d.

Depth of the fifth silicon oxide film 68e is set to, for example, 50 nm.

Next, a photoresist pattern (not illustrated) that exposes regions (hereinafter, referred to as removal regions 85) that are regions surrounding the membrane setting region 84 and that exclude the low resistance regions 72 and the flexible resistor regions 70 (regions that are to serve as the coupling portions 26 later) is formed.

In addition to the above, a photoresist pattern (not illustrated) that exposes, within the receptor forming region 31, a region (hereinafter, referred to as flat surface region 87) excluding the protruding portions forming the forming region-side recess/protrusion pattern 52a is formed. In the first embodiment, the photoresist pattern that exposes the flat surface region 87 is formed in such a way that the outer diameter of the protruding portions forming the forming region-side recess/protrusion pattern 52a is 2 μm.

Note that opening portions that are formed as a photoresist pattern exposing the removal regions 85 have a larger opening area than an opening portion that is formed as a photoresist pattern exposing the flat surface region 87. Note also that the photoresist pattern exposing the removal regions 85 and the photoresist pattern exposing the flat surface region 87 are, for example, formed at the same time, using the same mask.

Subsequently, as illustrated in FIG. 31B, portions of the fourth silicon oxide film 68d and fifth silicon oxide film 68e in the removal regions 85 and a portion of the fourth silicon oxide film 68d and fifth silicon oxide film 68e in the flat surface region 87 are removed by means of an etching technology.

Next, a photoresist pattern that exposes the removal regions 85 and a photoresist pattern (not illustrated) that exposes regions (hereinafter, referred to as recessed portion regions 88) corresponding to the recessed portions forming the exterior region-side recess/protrusion pattern 52b within the exterior region 32 are formed.

In the first embodiment, the photoresist pattern that exposes the recessed portion regions 88 is formed in such a way that the inner diameter of the recessed portions forming the exterior region-side recess/protrusion pattern 52b is 1 μm.

Note that opening portions that are formed as a photoresist pattern exposing the removal regions 85 have a larger opening area than opening portions that are formed as a photoresist pattern exposing the recessed portion regions 88. Note that the photoresist pattern exposing the removal regions 85 and the photoresist pattern exposing the recessed portion regions 88 are, for example, formed at the same time, using the same mask.

Succeedingly, etching is performed by, for example, reactive ion etching until portions of the second silicon substrate 64 in the removal regions 85 are penetrated, as illustrated in FIG. 31C. On this occasion, because of a magnitude relation between the opening areas and the fact that an etching rate in dry etching of silicon oxide film is lower than that in dry etching of silicon, the etching progresses only to an intermediate depth of the second silicon substrate 64 in the receptor forming region 31.

Last, by removing the photoresist by ashing or the like, the forming region-side recess/protrusion pattern 52a is formed in the receptor forming region 31 and, at the same time, the exterior region-side recess/protrusion pattern 52b is formed in the exterior region 32.

Consequently, in the forming region-side recess/protrusion pattern formation step and the exterior region-side recess/protrusion pattern formation step, the forming region-side recess/protrusion pattern 52a and the exterior region-side recess/protrusion pattern 52b are formed in such a way that the degree of roughness of the forming region-side recess/protrusion pattern 52a is lower than the degree of roughness of the exterior region-side recess/protrusion pattern 52b.

Therefore, in the forming region-side recess/protrusion pattern formation step, the forming region-side recess/protrusion pattern 52a is formed in such a way as to have a degree of roughness that allows the solution forming the receptor 30 to be present in gaps formed by a plurality of protruding portions or a plurality of recessed portions that form the forming region-side recess/protrusion pattern 52a. That is, in the forming region-side recess/protrusion pattern formation step, the forming region-side recess/protrusion pattern 52a is formed in such a way that the lyophilicity of the receptor forming region 31 is higher than the lyophilicity of the exterior region 32.

Further, in the exterior region-side recess/protrusion pattern formation step, the exterior region-side recess/protrusion pattern 52b is formed in such a way that the degree of roughness of the exterior region 32 is higher than the degree of roughness of the receptor forming region 31. Because of this configuration, in the exterior region-side recess/protrusion pattern formation step, the exterior region-side recess/protrusion pattern 52b is formed in such a way as to have a degree of roughness that enables the solution forming the receptor 30 to be prevented from infiltrating into gaps formed by a plurality of protruding portions or a plurality of recessed portions that form the exterior region-side recess/protrusion pattern 52b.

In addition, the forming region-side recess/protrusion pattern formation step, the exterior region-side recess/protrusion pattern formation step, and the removal step are performed at the same time.

### (Receptor Formation Step)

In the receptor formation step, a PEI solution or the like is applied to the receptor forming region 31, which is surrounded by the exterior region 32 in which the exterior region-side recess/protrusion pattern 52b is formed and, at the same time, has the forming region-side recess/protrusion pattern 52a formed therein, and is dried. Through this processing, the receptor 30 configured to be deformed according to an adsorbed substance is formed

### (Operation and Actions)

Referring to FIGS. 1 to 31, operation and actions of the first embodiment will be described.

When the surface stress sensor 1 is used as, for example, an olfactory sensor, the receptor 30 is arranged in an atmosphere of a gas containing odor components and the odor components contained by the gas are caused to adsorb to the receptor 30.

When molecules of the gas adsorb to the receptor 30 and a strain is induced in the receptor 30, surface stress is applied to the membrane 22 and the membrane 22 is bent.

The holding member 24 is formed in a quadrilateral and surrounds the membrane 22, and each of the coupling portions 26 couples the membrane 22 and the holding member 24 at both ends thereof. For this reason, in each coupling portion 26, the end coupled to the membrane 22 serves as a free end and the end coupled to the holding member 24 serves as a fixed end.

Therefore, when the membrane 22 is bent, bending matching a strain induced in the receptor 30 occurs in the coupling portions 26. The resistance values that the flexible resistors 50 have change according to the bending occurring in the coupling portions 26, and changes in voltage or current matching the changes in the resistance values are output from the PADs 86 and used in data detection in a computer or the like.

When a receptor 30 is formed in a surface stress sensor that has a conventional configuration, that is, when the receptor 30 is formed on a membrane 22 that has a configuration in which both a receptor forming region 31 and an exterior region 32 have the same affinity for a solution, the following problem may occur.

Since there is a possibility that a portion of a solution applied to the receptor forming region 31 spills out from the receptor forming region 31 to the exterior region 32, it is difficult to control the shape of the receptor to be formed in a desired shape (for example, a perfect circular cylinder) and there is a possibility that the shape of the receptor is formed in a shape deformed from the desired shape.

When the shape of the receptor is formed in a shape deformed from the desired shape, a strain occurring in the receptor 30 by molecules of a gas adsorbing to the receptor 30 is caused to have a value different from an expected value, such as a design value. Thus, when molecules of the gas adsorb to the receptor 30 at the time of using the surface stress sensor as an olfactory sensor, bending induced to coupling portions 26 according to the strain occurring in the receptor 30 is caused to be different from expected bending and resistance change occurring in flexible resistors 50 has a value different from an expected value. This means that sensitivity as a sensor decreases.

Therefore, there is concern that, in the surface stress sensor having the conventional configuration, the sensitivity of the surface stress sensor deteriorates.

On the other hand, in the case of the surface stress sensor 1 of the first embodiment, the forming region-side recess/protrusion pattern 52a is formed in the receptor forming region 31. In addition, the forming region-side recess/protrusion pattern 52a is a pattern that causes the degree of roughness of the receptor forming region 31 to be lower than the degree of roughness of the exterior region 32. That is, the forming region-side recess/protrusion pattern 52a is a pattern having a degree of roughness that allows the solution forming the receptor 30 to be present in gaps formed by the plurality of protruding portions or the plurality of recessed portions that form the forming region-side recess/protrusion pattern 52a.

In addition to the above, the exterior region-side recess/protrusion pattern 52b is formed in a concentric manner with respect to the membrane 22. In addition, the exterior region-side recess/protrusion pattern 52b is a pattern that exhibits lyophobic action due to the lotus effect and that causes the degree of roughness of the exterior region 32 to be higher than the degree of roughness of the receptor forming region 31.

Thus, it becomes possible to improve controllability to control the shape of the receptor 30 to be formed in a desired shape (for example, a perfect circular cylinder). Therefore, there is no chance that the sensitivity of the surface stress sensor 1 deteriorates.

It should be noted that the foregoing first embodiment is one example of the present invention, the present invention is not limited to the foregoing first embodiment, and, even when the present invention may be carried out in modes other than the embodiment, depending on designs, various changes may be made to the present invention within a scope not departing from the technical idea of the present invention

### Advantageous Effects of First Embodiment

The surface stress sensor 1 of the first embodiment enables advantageous effects that will be described below to be attained.
(1) The surface stress sensor 1 of the first embodiment includes the membrane 22 configured to be bent by applied surface stress, the holding member 24 arranged on the outer side of the membrane 22, the coupling portions 26 configured to couple the membrane 22 and the holding member 24, and the flexible resistors 50 configured to have resistance values changing according to bending induced in the coupling portions 26.

In addition to the above, the surface stress sensor 1 includes the forming region-side recess/protrusion pattern 52a formed on the front surface of the membrane 22 and formed with a pattern in which a plurality of protruding portions or a plurality of recessed portions continue. The forming region-side recess/protrusion pattern 52a is formed in the receptor forming region 31 within the front surface of the membrane 22. In addition, the forming region-side recess/protrusion pattern 52a is a pattern having a degree of roughness that allows the solution forming the receptor 30 to be present in gaps formed by the plurality of protruding portions or the plurality of recessed portions that form the forming region-side recess/protrusion pattern 52a.

Therefore, forming the forming region-side recess/protrusion pattern 52a in the receptor forming region 31 within the front surface of the membrane 22 causes the affinity of the receptor forming region 31 for the solution to be higher than the affinity of the exterior region 32 for the solution.

Because of this configuration, the solution applied to the receptor forming region 31 is facilitated to spread in the receptor forming region 31 by lyophilicity improved by the forming region-side recess/protrusion pattern 52a (Wenzel effect). In addition to the above, lyophobicity that the exterior region 32 has enables the solution applied to the receptor forming region 31 to be prevented from spilling out to the exterior region 32.

As a result, it becomes possible to provide the surface stress sensor 1 that enables the controllability to control the receptor 30 to be formed in a desired shape to be improved.

In addition, since the affinity of the receptor forming region 31 for the solution is high, even when the amount of the solution applied to the receptor forming region 31 is increased, the solution is facilitated to spread in the receptor forming region 31 by lyophilicity improved by the forming region-side recess/protrusion pattern 52a. In addition to the above, lyophobicity that the exterior region 32 has enables the solution applied to the receptor forming region 31 to be prevented from spilling out to the exterior region 32.

Therefore, even when the amount of the solution applied to the receptor forming region 31 is increased, the solution smoothly spreads in the receptor forming region 31. Thus, even when portions where film thickness is large and portions where film thickness is small are formed in the receptor 30, it becomes possible to control a difference in thickness between the portions where film thickness is large and the portions where film thickness is small and thereby improve the controllability to control the receptor 30 to be formed in a desired shape.
(2) The surface stress sensor 1 of the first embodiment includes the exterior region-side recess/protrusion pattern 52b formed in the exterior region 32 and formed with a pattern in which a plurality of protruding portions or a plurality of recessed portions continue. In addition, the exterior region-side recess/protrusion pattern 52b is a pattern having a degree of roughness that enables the solution forming the receptor 30 to be prevented from infiltrating into gaps formed by the plurality of protruding portions or the plurality of recessed portions that form the exterior region-side recess/protrusion pattern 52b.

Therefore, forming the exterior region-side recess/protrusion pattern 52b, which causes the exterior region 32 to have a higher degree of roughness than the receptor forming region 31, in the exterior region 32 within the front surface of the membrane 22 causes the affinity of the exterior region 32 for the solution to be lower than the affinity of the receptor forming region 31 for the solution.

Because of this configuration, it becomes possible to prevent the solution applied to the receptor forming region 31 from spilling out from the receptor forming region 31 to the exterior region 32 by lyophobicity of the exterior region 32 improved by the exterior region-side recess/protrusion pattern 52b.

As a result, it becomes possible to further improve the controllability to control the receptor 30 to be formed in a desired shape, compared with a configuration in which the exterior region-side recess/protrusion pattern 52b is not formed.
(3) The surface stress sensor 1 of the first embodiment includes the receptor 30 formed on the receptor forming region 31 and configured to be deformed according to an adsorbed substance and has the exterior region-side recess/protrusion pattern 52b formed in a shape matching the physical properties of the receptor 30.

As a result, it becomes possible to set the lyophobicity of the exterior region-side recess/protrusion pattern 52b to a value matching the physical properties of the receptor 30.
(4) Each of the protruding portions or the recessed portions forming the exterior region-side recess/protrusion pattern 52b is formed in a circle when viewed from the thickness direction of the membrane 22.

As a result, the formation of the exterior region-side recess/protrusion pattern 52b is facilitated.
(5) The degree of roughness of the forming region-side recess/protrusion pattern 52a is lower than the degree of roughness of the exterior region 32.

Since, as a result, the affinity of the receptor forming region 31 for the solution is higher than the affinity of the exterior region 32 for the solution, it becomes possible to improve the controllability to control the receptor 30 to be formed in a desired shape.
(6) The surface stress sensor 1 of the first embodiment includes the receptor 30 formed on the receptor forming region 31 and configured to be deformed according to an adsorbed substance and has the forming region-side recess/protrusion pattern 52a formed in a shape matching the physical properties of the receptor 30.

As a result, it becomes possible to set the lyophilicity of the forming region-side recess/protrusion pattern 52a to a value matching the physical properties of the receptor 30.
(7) Each of the protruding portions or the recessed portions forming the forming region-side recess/protrusion pattern 52a is formed in a circle when viewed from the thickness direction of the membrane 22.

As a result, the formation of the forming region-side recess/protrusion pattern 52a is facilitated.

In addition, the method for manufacturing the surface stress sensor of the first embodiment enables advantageous effects that will be described below to be attained.
(8) The method for manufacturing the surface stress sensor of the first embodiment includes the forming region-side recess/protrusion pattern formation step. In the forming region-side recess/protrusion pattern formation step, the forming region-side recess/protrusion pattern 52a is formed in the receptor forming region 31 in such a way as to have a degree of roughness that allows the solution to be present in gaps formed by the plurality of protruding portions or the plurality of recessed portions that form the forming region-side recess/protrusion pattern 52a.

Therefore, forming the forming region-side recess/protrusion pattern 52a, which causes the lyophilicity of the receptor forming region 31 to be higher than that of the exterior region 32, in the receptor forming region 31 within the front surface of the membrane 22 causes the affinity of the receptor forming region 31 for the solution to be higher than the affinity of the exterior region 32 for the solution.

Because of this configuration, the solution applied to the receptor forming region 31 is facilitated to spread in the receptor forming region 31 by lyophilicity improved by the forming region-side recess/protrusion pattern 52a. In addition to the above, lyophobicity that the exterior region 32 has enables the solution applied to the receptor forming region 31 to be prevented from spilling out to the exterior region 32.

As a result, it becomes possible to provide the method for manufacturing the surface stress sensor that enables the controllability to control the receptor 30 to be formed in a desired shape to be improved.

In addition, since the affinity of the receptor forming region 31 for the solution is high, even when the amount of the solution applied to the receptor forming region 31 is increased, the solution is facilitated to spread in the receptor forming region 31 by lyophilicity improved by the forming region-side recess/protrusion pattern 52a. In addition to the above, lyophobicity that the exterior region 32 has enables the solution applied to the receptor forming region 31 to be prevented from spilling out to the exterior region 32.

Since, therefore, even when the amount of the solution applied to the receptor forming region 31 is increased, the solution smoothly spreads in the receptor forming region 31, it becomes possible to suppress unevenness generated in the thickness of the receptor 30 and thereby improve the controllability to control the receptor 30 to be formed in a desired shape.
(9) The forming region-side recess/protrusion pattern formation step and the removal step are performed at the same time.

As a result, it becomes possible to simplify the manufacturing process of the surface stress sensor 1.
(10) The method for manufacturing the surface stress sensor further includes the exterior region-side recess/protrusion pattern formation step of forming a plurality of exterior region-side recess/protrusion patterns 52b. In addition to the above, in the exterior region-side recess/protrusion pattern formation step, the exterior region-side recess/protrusion pattern 52b is formed in such a way as to have a degree of roughness that enables the solution to be prevented from infiltrating into gaps formed by the plurality of protruding portions or the plurality of recessed portions that form the exterior region-side recess/protrusion pattern 52b.

Because of this configuration, it becomes possible to prevent the solution applied to the receptor forming region 31 from spilling out from the receptor forming region 31 to the exterior region 32 by the lyophobicity of the exterior region 32 improved by the exterior region-side recess/protrusion pattern 52b.

As a result, it becomes possible to further improve the controllability to control the receptor 30 to be formed in a desired shape, compared with a configuration in which the exterior region-side recess/protrusion pattern 52b is not formed.
(11) The forming region-side recess/protrusion pattern formation step and the exterior region-side recess/protrusion pattern formation step are performed at the same time.

As a result, it becomes possible to simplify the manufacturing process of the surface stress sensor 1.
(12) The exterior region-side recess/protrusion pattern formation step and the removal step are performed at the same time.

As a result, it becomes possible to simplify the manufacturing process of the surface stress sensor 1.
(13) In the forming region-side recess/protrusion pattern formation step and the exterior region-side recess/protrusion pattern formation step, the forming region-side recess/protrusion pattern 52a and the exterior region-side recess/protrusion pattern 52b are formed in such a way that the degree of roughness of the forming region-side recess/protrusion pattern 52a is lower than the degree of roughness of the exterior region-side recess/protrusion pattern 52b.

Since, as a result, the affinity of the receptor forming region 31 for the solution is higher than the affinity of the exterior region 32 for the solution, it becomes possible to improve the controllability to control the receptor 30 to be formed in a desired shape.

### Variations of First Embodiment

(1) Although, in the first embodiment, the cavity portion 40 was formed between the membrane 22 and the support base member 10 by forming the recessed portion 62 on one surface of the first silicon substrate 60, which serves as a material of the support base member 10, the present invention is not limited to the configuration. That is, the cavity portion 40 may be formed between the membrane 22 and the support base member 10 by forming a recessed portion on a surface of the second silicon substrate 64, which serves as a material of the detection base member 20, facing the support base member 10.
(2) Although, in the first embodiment, the surface stress sensor 1 had a configuration in which, on the four coupling portions 26a to 26d constituting two pairs, the flexible resistors 50a to 50d are disposed, respectively, the present invention is not limited to the configuration. That is, the surface stress sensor 1 may have a configuration in which, on each of two coupling portions 26 constituting a pair, a flexible resistor 50 is disposed.
(3) Although, in the first embodiment, the surface stress sensor 1 had a configuration in which, on all the four coupling portions 26a to 26d, the flexible resistors 50 are disposed, the present invention is not limited to the configuration, and the surface stress sensor 1 may have a configuration in which, on at least one coupling portion 26, a flexible resistor 50 is disposed.
(4) Although, in the first embodiment, the area of the connecting portion 4 was set to a value smaller than the area of the membrane 22 when viewed from the thickness direction of the membrane 22, the present invention is not limited to the configuration, and the area of the connecting portion 4 may be set to a value equal to or greater than the area of the membrane 22.
(5) Although, in the first embodiment, the shape of the connecting portion 4 was set to a circle, the present invention is not limited to the configuration and the shape of the connecting portion 4 may be set to a square. In addition, a plurality of connecting portions 4 may be formed.
(6) Although, in the first embodiment, the same material was used as a material of which the detection base member 20 is formed and a material of which the support base member 10 is formed, the present invention is not limited to the configuration, and different materials may be used as the material of which the detection base member 20 is formed and the material of which the support base member 10 is formed.

In this case, setting a difference between a value of the linear expansion coefficient of the detection base member 20 and a value of the linear expansion coefficient of the support base member 10 to be 1.2×10⁻⁵/° C. or less enables a difference between the amount of deformation of the detection base member 20 and the amount of deformation of the support base member 10 matching deformation of the package substrate 2 to be decreased. This configuration enables bending of the membrane 22 to be suppressed.
(7) Although, in the first embodiment, the value of linear expansion coefficient of the support base member 10 was set to 5.0×10⁻⁶/° C. or less, the present invention is not limited to the configuration, and the value of linear expansion coefficient of the support base member 10 may be set to 1.0×10⁻⁵/° C. or less.

Even in this case, it becomes possible to improve rigidity of the support base member 10 and it thereby becomes possible to decrease the amount of deformation of the detection base member 20 with respect to deformation of the package substrate 2 caused by temperature change and the like.
(8) Although, in the first embodiment, the exterior region-side recess/protrusion pattern 52b was formed on the exterior region 32, the present invention is not limited to the configuration.

That is, the degree of roughness of the exterior region 32 may be set higher than the degree of roughness of the receptor forming region 31 by causing the exterior region 32 to have roughness high enough to have the lotus effect through, for example, subjecting the exterior region 32 to a knurling process.

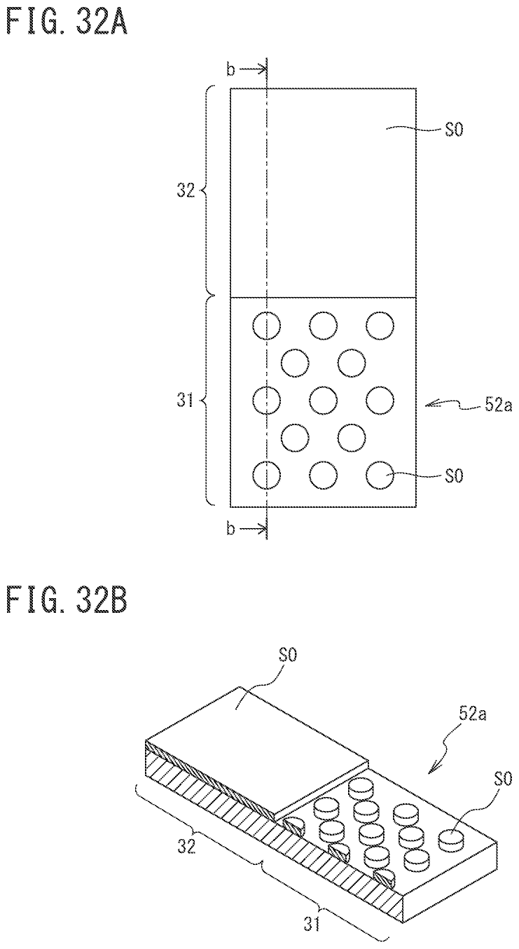

In the case of this configuration, when a hydrophilic solution is applied to the membrane 22, it is possible to form the receptor 30 having high adhesion with the membrane 22 because the receptor forming region 31 has high wettability. On the other hand, the exterior region 32 comes to have a strong lyophobic function because the lotus effect is added to lyophobicity of silicon, and, hence, it becomes possible to improve the action of preventing the solution from flowing out.
(9) Although, in the first embodiment, the forming region-side recess/protrusion pattern 52a and the exterior region-side recess/protrusion pattern 52b were formed, the present invention is not limited to the configuration. That is, for example, without forming the exterior region-side recess/protrusion pattern 52b in the exterior region 32, the exterior region 32 may be formed in a plane (a smooth surface or a flat surface) on which neither a protruding portion nor a recessed portion is formed and on the surface of which an oxide film SO is formed, as illustrated in FIGS. 32A and 32B. That is, the exterior region 32 (second surface region) may be formed in a smooth surface.

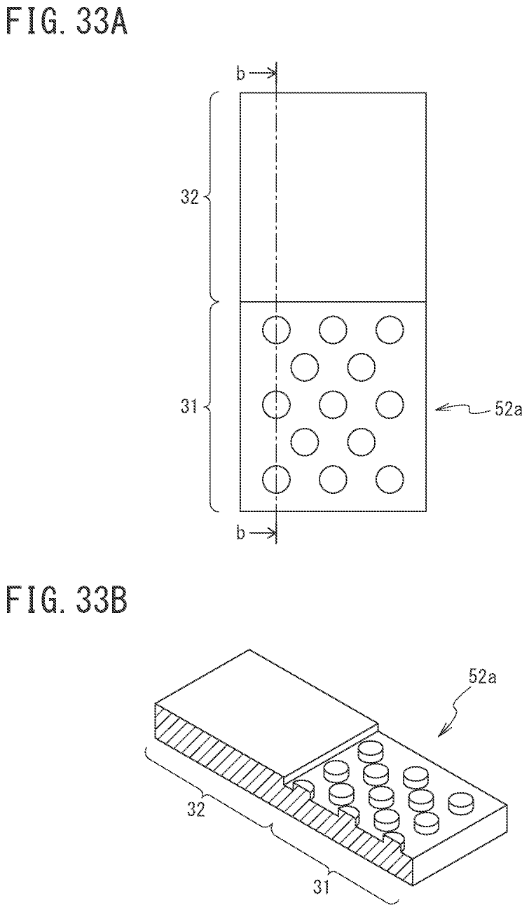

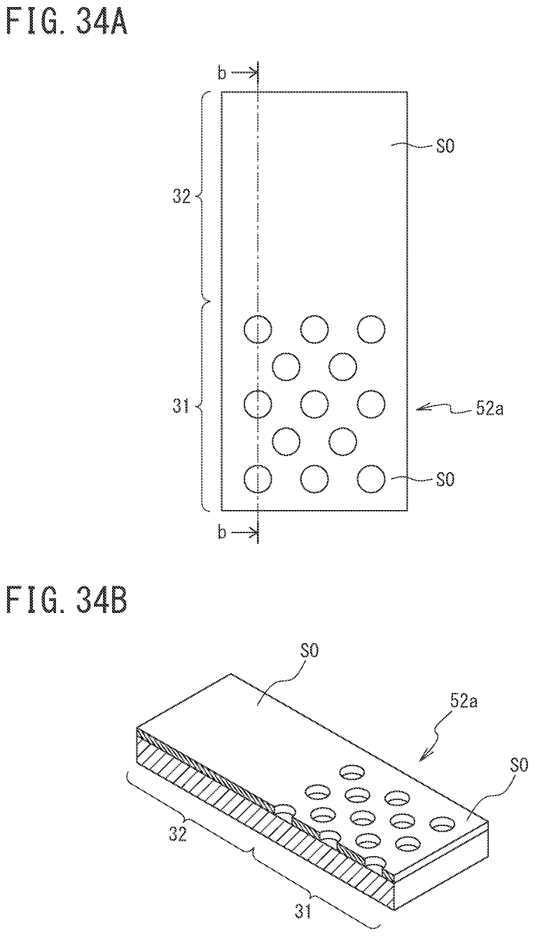

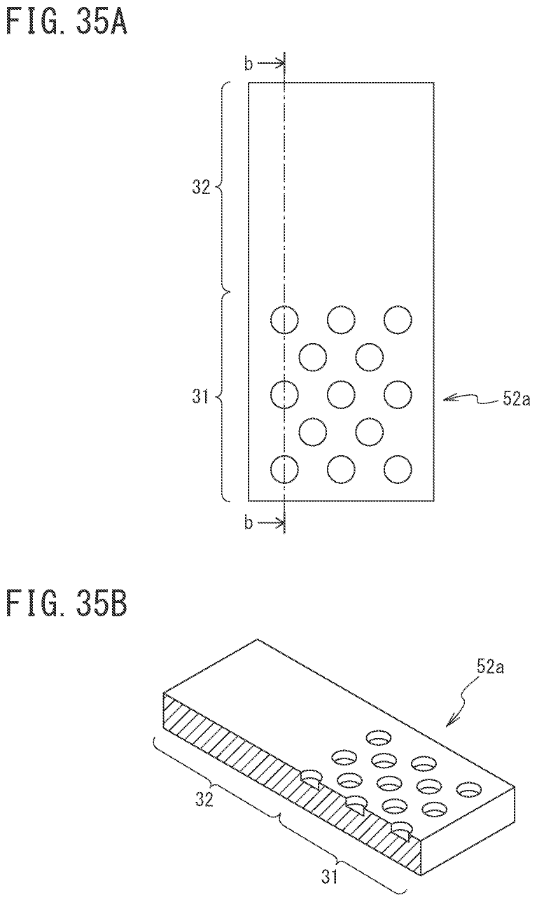

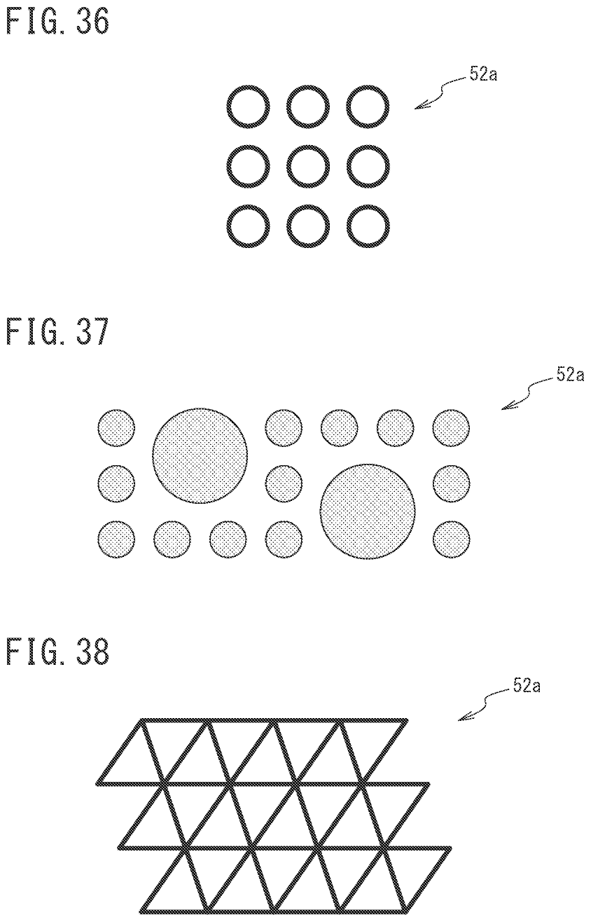

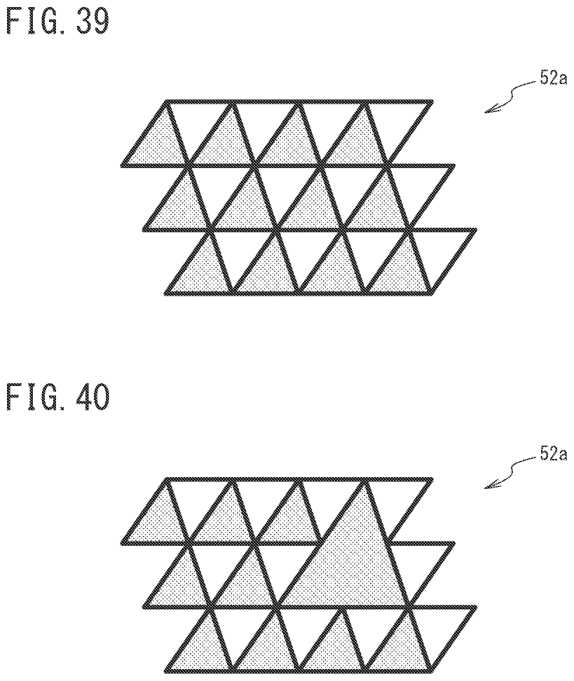

In this case, for example, the exterior region 32 may be configured to have silicon exposed, as illustrated in FIGS. 33A and 33B. In addition, for example, as illustrated in FIGS. 34A and 34B, the forming region-side recess/protrusion pattern 52a may be configured to be formed by a plurality of recessed portions. In addition, for example, it may be configured such that, as illustrated in FIGS. 35A and 35B, the exterior region 32 has silicon exposed and, at the same time, the forming region-side recess/protrusion pattern 52a is formed by a plurality of recessed portions.
(10) Although, in the first embodiment, the forming region-side recess/protrusion pattern 52a was formed by a plurality of protruding portions formed into pillars, the present invention is not limited to the configuration. That is, for example, as illustrated in the FIG. 36, the forming region-side recess/protrusion pattern 52a may be formed by a plurality of protruding portions formed into hollow cylinders. Note that the same applies to the exterior region-side recess/protrusion pattern 52b.
(11) Although, in the first embodiment, the plurality of protruding portions (pillars) forming the forming region-side recess/protrusion pattern 52a were formed in the same shape (outer diameter and height), the present invention is not limited to the configuration. That is, for example, as illustrated in the FIG. 37, the forming region-side recess/protrusion pattern 52a may be formed by a plurality of protruding portions having different shapes, such as being formed by a plurality of protruding portions having different outer diameters. In addition, the same applies to the case where the forming region-side recess/protrusion pattern 52a is formed by recessed portions. Note that the same applies to the exterior region-side recess/protrusion pattern 52b.
(12) Although, in the first embodiment, the protruding portions forming the forming region-side recess/protrusion pattern 52a were formed in circles when viewed from the thickness direction of the membrane 22, the present invention is not limited to the configuration. That is, for example, as illustrated in FIG. 38, the protruding portions forming the forming region-side recess/protrusion pattern 52a may be formed with a pattern in which line segments forming triangles are closely arranged when viewed from the thickness direction of the membrane 22. In addition, for example, as illustrated in FIG. 39, the protruding portions forming the forming region-side recess/protrusion pattern 52a may be formed with a pattern in which line segments forming triangles and triangular prisms are closely arranged in a mixed manner when viewed from the thickness direction of the membrane 22. Further, for example, as illustrated in FIG. 40, the protruding portions forming the forming region-side recess/protrusion pattern 52a may be formed with a pattern in which line segments forming triangles and triangular prisms having different areas are closely arranged in a mixed manner when viewed from the thickness direction of the membrane 22. Note that the same applies to the exterior region-side recess/protrusion pattern 52b.
(13) Although, in the first embodiment, the surface stress sensor 1 was configured to include the package substrate 2, the connecting portion 4, the detection base member 20, and the support base member 10, the present invention is not limited to the configuration. That is, the surface stress sensor 1 may be configured to include the package substrate 2, the connecting portion 4, and the detection base member 20. That is, the surface stress sensor 1 may be configured not to include the support base member 10.
(14) Although, in the first embodiment, the holding member 24 was configured to be formed in a quadrilateral (square) frame shape and surround the membrane 22 with gaps interposed therebetween, the present invention is not limited to the configuration. That is, the holding member 24 may be configured to be formed in, for example, a quadrilateral other than a square, such as a rhombus. In addition, the holding member 24 may be configured to be formed in, for example, a discontinuous shape having an opening portion, such as a U-shape. That is, the configuration of the holding member 24 is only required to be a configuration that enables the membrane 22 to be supported and fixed from the outside.

### Second Embodiment

Hereinafter, a second embodiment of the present invention will be described with reference to the drawings.

### (Configuration)

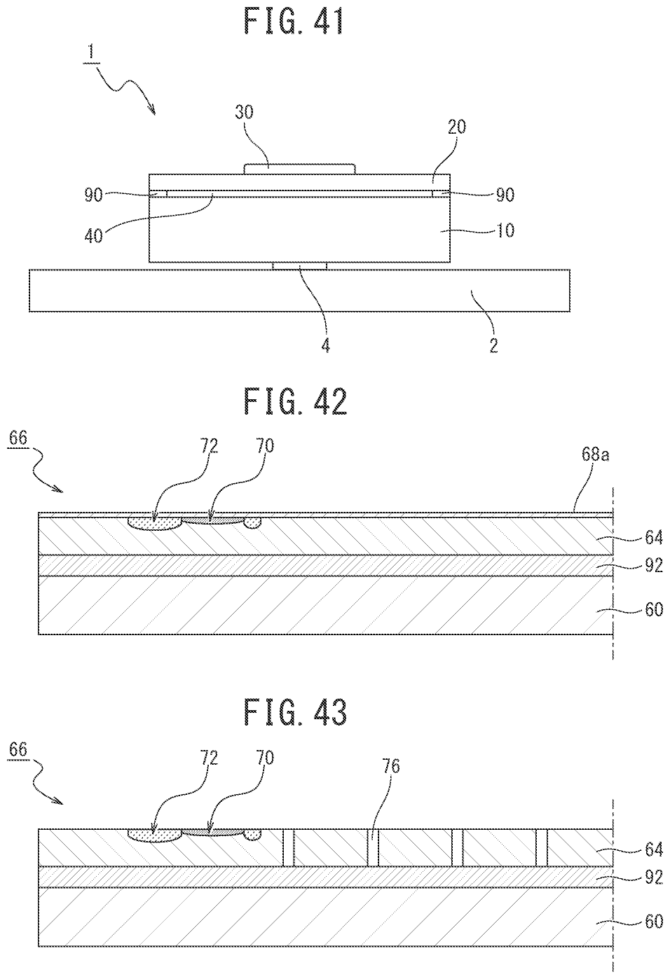

Using FIG. 41 while referring to FIGS. 1 to 40, a configuration of the second embodiment will be described.

The configuration of the second embodiment is the same as that of the first embodiment described above except that, as illustrated in FIG. 41, a holding member 24 is connected to a surface (in FIG. 41, the surface on the upper side) of a support base member 10 on the opposite side to a surface thereof facing a package substrate 2 with a connecting layer 90 interposed therebetween.

The connecting layer 90 is formed of silicon dioxide (SiO₂) or the like.

Since a configuration of the other constituent components is the same as that of the first embodiment described above, a description thereof will be omitted.

### (Method for Manufacturing Surface Stress Sensor)

Using FIGS. 42 to 45 while referring to FIGS. 1 to 41, a method for manufacturing a surface stress sensor 1 will be described. Note that cross-sectional views in FIGS. 42 to 45 correspond to a cross-sectional view taken along the line X-X in FIG. 5.

The method for manufacturing the surface stress sensor 1 includes a stacked body formation step, a first ion implantation step, a second ion implantation step, a heat treatment step, a hole formation step, a cavity portion formation step, and a hole sealing step. In addition to the above, the method for manufacturing the surface stress sensor 1 includes a forming region-side recess/protrusion pattern formation step, an exterior region-side recess/protrusion pattern formation step, a receptor formation step, a removal step, and a wiring layer formation step.

### (Stacked Body Formation Step)

In the stacked body formation step, first, a sacrificial layer 92 that is formed of silicon oxide film is stacked on a first silicon substrate 60 that serves as a material of the support base member 10, as illustrated in FIG. 42. Further, on the sacrificial layer 92, a second silicon substrate 64 that serves as a material of a detection base member 20 is stacked. Note that, as the sacrificial layer 92, silicon nitride film or metal film made of a metal, such as aluminum, titanium, copper, and tungsten, may be used in place of silicon oxide film.

Consequently, in the stacked body formation step, by stacking the sacrificial layer 92 on the support base member 10 and further stacking the detection base member 20 on the sacrificial layer 92, a stacked body 66 is formed.

### (First Ion Implantation Step)

In the first ion implantation step, first, a surface on the upper side of the second silicon substrate 64 is oxidized by oxidizing the second silicon substrate 64 and a first silicon oxide film 68a is thereby formed, as illustrated in FIG. 42.

Next, a photoresist pattern (not illustrated) is formed over the second silicon substrate 64 on which the first silicon oxide film 68a is formed, and first ions are selectively implanted into flexible resistor regions 70.

Consequently, in the first ion implantation step, the first ions are implanted into selected partial regions (the flexible resistor regions 70) on the outer side of a preset region including the center of the detection base member 20 within a surface of the detection base member 20 on the opposite side to a surface thereof facing the support base member 10.

### (Second Ion Implantation Step)

In the second ion implantation step, the photoresist used in the first ion implantation step is removed, a photoresist pattern (not illustrated) different from the photoresist pattern used in the first ion implantation step is further formed, and second ions are implanted into low resistance regions 72.

Consequently, in the second ion implantation step, the second ions are implanted into selected regions on the outer side of the regions (the flexible resistor regions 70) into which the first ions were implanted on the detection base member 20.

### (Heat Treatment Step)

In the heat treatment step, the photoresist used in the second ion implantation step is removed, and, further, the stacked body 66 is subjected to heat treatment (annealing treatment) with the aim of activation of the first ions and the second ions. After the stacked body 66 has been subjected to the heat treatment, the first silicon oxide film 68a is removed.

Consequently, in the heat treatment step, by subjecting the stacked body 66, into which the first ions and the second ions were implanted, to heat treatment, the flexible resistor regions 70 are formed in the regions into which the first ions were implanted and the low resistance regions 72 are also formed in the regions into which the second ions were implanted.

### (Hole Formation Step)

In the hole formation step, by means of a general photolithography technology, a pattern of holes (not illustrated) is formed on a surface on the upper side of the second silicon substrate 64.

Next, dry etching is performed using the pattern of holes as a mask, and, as illustrated in FIG. 43, holes 76 are formed in the second silicon substrate 64. Diameter of each hole 76 is set to, for example, 0.28 μm, and depth of each hole 76 is set to a depth that allows the hole 76 to reach the sacrificial layer 92.

Consequently, in the hole formation step, the holes 76 that penetrate the second silicon substrate 64 to the sacrificial layer 92 are formed in regions of the detection base member 20 adjacent to the regions thereof in which the flexible resistor regions 70 and the low resistance regions 72 were formed.

### (Cavity Portion Formation Step)

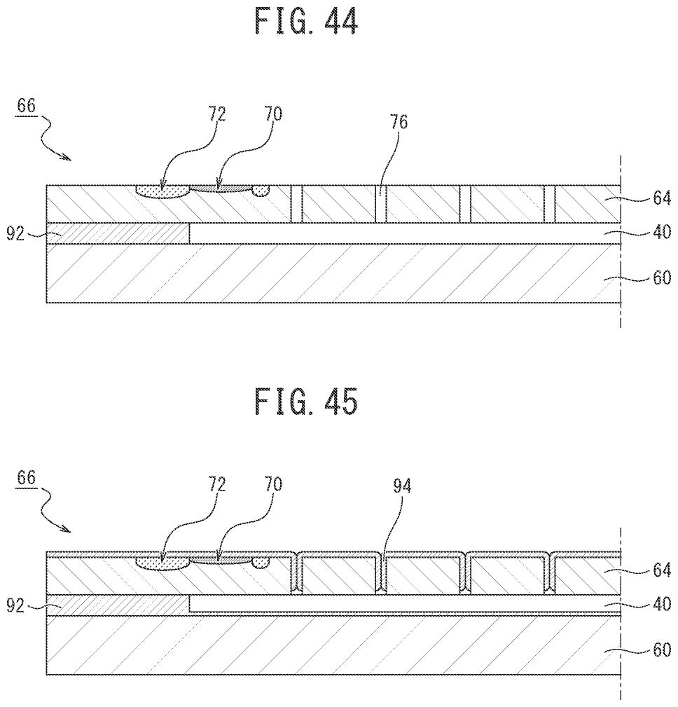

In the cavity portion formation step, only the sacrificial layer 92 is selectively etched by causing HF Vapor to permeate to the side on which the first silicon substrate 60 is located through the holes 76, and, as illustrated in FIG. 44, a cavity portion 40 is formed between the first silicon substrate 60 and the second silicon substrate 64.

The reason for not using wet etching with HF in the step is to avoid occurrence of a trouble (also referred to as sticktion) in which, at the time of drying after the formation of the cavity portion 40, the cavity portion 40 is crushed due to surface tension of pure water or the like.

Consequently, in the cavity portion formation step, a portion of the sacrificial layer 92 arranged between the flexible resistor regions 70 and the support base member 10 is removed by etching via the holes 76 and the cavity portion 40 is thereby formed between the support base member 10 and the detection base member 20.

### (Hole Sealing Step)

In the hole sealing step, as illustrated in FIG. 45, the holes 76 are sealed by an oxide film 94.

Although, as a method for sealing the holes 76, for example, a combination of thermal oxidation treatment and CVD or the like is effective, it is possible to use only CVD when the diameter of each hole 76 is small.

Consequently, in the hole sealing step, the oxide film 94 is formed on the surface of the detection base member 20 on the opposite side to the surface thereof facing the support base member 10 and the holes 76 are thereby sealed.

### (Wiring Layer Formation Step)

Since the wiring layer formation step is performed in the same procedure as that of the first embodiment described above, a description thereof will be omitted.

Consequently, in the wiring layer formation step, a wiring layer 82 that is electrically connected to flexible resistors 50 is formed.

### (Forming Region-Side Recess/Protrusion Pattern Formation

Step, Exterior Region-Side Recess/Protrusion Pattern Formation Step, and Removal Step)

Since the forming region-side recess/protrusion pattern formation step, the exterior region-side recess/protrusion pattern formation step, and the removal step are performed in the same procedures as those of the first embodiment described above, descriptions thereof will be omitted.

### (Receptor Formation Step)

In the receptor formation step, on a receptor forming region 31, a receptor 30 configured to be deformed according to an adsorbed substance is formed by applying and drying a PEI solution or the like.

### (Operation and Actions)

Since operation and actions of the second embodiment are the same as those of the first embodiment described above, descriptions thereof will be omitted.

It should be noted that the foregoing second embodiment is one example of the present invention, the present invention is not limited to the foregoing second embodiment, and, even when the present invention may be carried out in modes other than the embodiment, depending on designs, various changes may be made to the present invention within a scope not departing from the technical idea of the present invention

### Advantageous Effects of Second Embodiment

In the case of the method for manufacturing the surface stress sensor of the second embodiment, as with the first embodiment, it becomes possible to provide a method for manufacturing the surface stress sensor that enables controllability to control the receptor 30 to be formed in a desired shape to be improved.

### Third Embodiment

Hereinafter, a third embodiment of the present invention will be described with reference to the drawings.

### (Configuration)

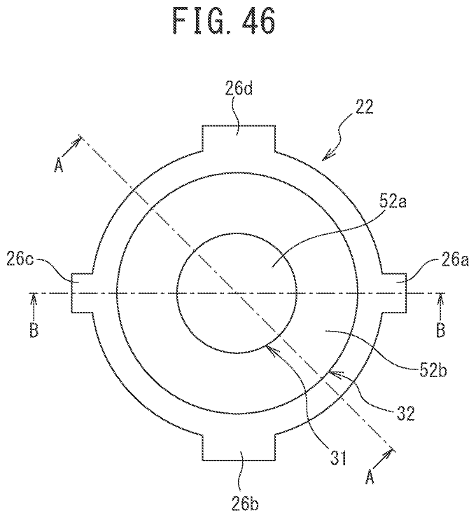

Using FIGS. 46 to 49 while referring to FIGS. 1 to 45, a configuration of the third embodiment will be described.

The configuration of the third embodiment is the same as that of the first embodiment described above except configurations of a forming region-side recess/protrusion pattern 52a and an exterior region-side recess/protrusion pattern 52b.

The forming region-side recess/protrusion pattern 52a is formed in a receptor forming region 31 (first surface region) within the front surface of a membrane 22.

In addition, the forming region-side recess/protrusion pattern 52a is formed with a pattern in which a plurality of protruding portions (protrusions or pillars) or a plurality of recessed portions (openings or holes) are consecutively repeated. In the third embodiment, a case where the forming region-side recess/protrusion pattern 52a is formed by a plurality of recessed portions will be described as an example.

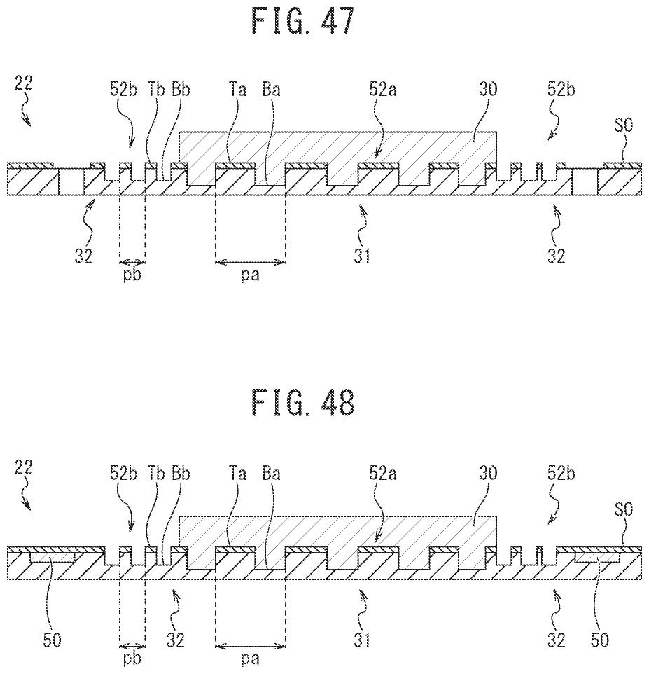

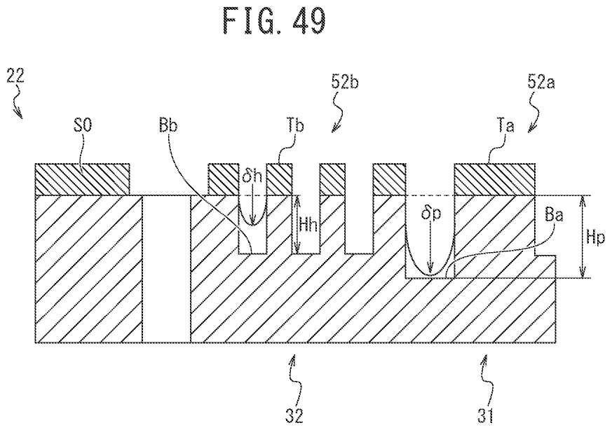

Therefore, as illustrated in FIGS. 47 and 48, a cross-section of the forming region-side recess/protrusion pattern 52a is a shape in which recessed portions are arranged.

The exterior region-side recess/protrusion pattern 52b is formed in an exterior region 32 (second surface region) within the front surface of the membrane 22.

In addition, the exterior region-side recess/protrusion pattern 52b is, as with the forming region-side recess/protrusion pattern 52a, formed with a pattern in which a plurality of protruding portions or a plurality of recessed portions are consecutively repeated. In the third embodiment, a case where the exterior region-side recess/protrusion pattern 52b is formed by a plurality of recessed portions (holes) will be described as an example.

Therefore, as illustrated in FIGS. 47 and 48, a cross-section of the exterior region-side recess/protrusion pattern 52b is a shape in which recessed portions are arranged.

In addition, the exterior region-side recess/protrusion pattern 52b is formed using the above-described equations (11) and (12) in such a manner that the exterior region 32, in which the exterior region-side recess/protrusion pattern 52b is formed, has lyophobicity against a solution.

In addition, pitch, inner diameter of the recessed portions, depth of the recessed portions of the exterior region-side recess/protrusion pattern 52b are set to values matching physical properties of the receptor 30 (physical properties of a solution forming the receptor 30). That is, the exterior region-side recess/protrusion pattern 52b is formed in a shape matching the physical properties of the receptor 30.

As described above, the forming region-side recess/protrusion pattern 52a is a pattern that causes lyophilicity of the receptor forming region 31 to be higher than lyophilicity of the exterior region 32. Further, the exterior region-side recess/protrusion pattern 52b is a pattern having a degree of roughness that enables the solution forming the receptor 30 to be prevented from infiltrating into gaps formed by the plurality of protruding portions or the plurality of recessed portions that form the exterior region-side recess/protrusion pattern 52b.

Next, specific configurations of the forming region-side recess/protrusion pattern 52a and the exterior region-side recess/protrusion pattern 52b will be described.

The forming region-side recess/protrusion pattern 52a and the exterior region-side recess/protrusion pattern 52b are formed in such a way that, as illustrated in FIG. 49, depth Hp of the recessed portions forming the forming region-side recess/protrusion pattern 52a is greater than depth Hh of the recessed portions forming the exterior region-side recess/protrusion pattern 52b.

That is, a relationship between the depth Hp of the recessed portions forming the forming region-side recess/protrusion pattern 52a and the depth Hh of the recessed portions forming the exterior region-side recess/protrusion pattern 52b is a relationship expressed by the equation (14) below.

Hh<Hp (14)

Therefore, as illustrated in FIG. 49, when viewed from a direction orthogonal to the thickness direction of the membrane 22, a difference in height (equivalent to “Hp”) between a top surface Ta and bottom surfaces Ba that are formed in the forming region-side recess/protrusion pattern 52a is greater than a difference in height (equivalent to “Hh”) between a top surface Tb and bottom surfaces Bb that are formed in the exterior region-side recess/protrusion pattern 52b.

Note that the “direction orthogonal to the thickness direction of the membrane 22” is the same direction as a “direction in which a surface stress sensor 1 is viewed from a side surface”.

In addition, the “top surface Ta” is the top surface of an oxide film SO formed on the receptor forming region 31, and the “top surface Tb” is the top surface of an oxide film SO formed on the exterior region 32.

In addition, in the third embodiment, the forming region-side recess/protrusion pattern 52a and the exterior region-side recess/protrusion pattern 52b are formed in such a way that a relational equation δp>δh holds based on the equation (12).

“δp” denotes a difference in height (thickness of a recess) between a point within a surface of the solution applied to an interspace between protruding portions (top surface Ta) adjacent to each other at which a difference in height from the tops of the protruding portions is largest (a point at which the surface is most recessed) and the tops of the protruding portions in the forming region-side recess/protrusion pattern 52a, as illustrated in FIG. 49.

“δh” denotes a difference in height (thickness of a recess) between a point within a surface of the solution applied to an interspace between protruding portions (top surface Tb) adjacent to each other at which a difference in height from the tops of the protruding portions is largest (a point at which the surface is most recessed) and the tops of the protruding portions in the exterior region-side recess/protrusion pattern 52b, as illustrated in FIG. 49.

In addition, as illustrated in FIGS. 47 and 48, when viewed from the thickness direction of the membrane 22, pitch pa between recessed portions adjacent to each other forming the forming region-side recess/protrusion pattern 52a is greater than pitch pb between recessed portions adjacent to each other forming the exterior region-side recess/protrusion pattern 52b.

Further, when viewed from the thickness direction of the membrane 22, total area of the bottom surfaces Ba is greater than total area of the bottom surfaces Bb.

That is, when viewed from the thickness direction of the membrane 22, a ratio of the area of the recessed portions (bottom surfaces Ba) to total area of the forming region-side recess/protrusion pattern 52a is greater than a ratio of the area of the recessed portions (bottom surfaces Bb) to total area of the exterior region-side recess/protrusion pattern 52b.

Since a configuration of the other constituent components is the same as that of the first embodiment described above, a description thereof will be omitted.

### (Method for Manufacturing Surface Stress Sensor)

Referring to FIGS. 1 to 49, a method for manufacturing the surface stress sensor 1 will be described.

The method for manufacturing the surface stress sensor 1 includes a stacked body formation step, a first ion implantation step, a second ion implantation step, a heat treatment step, a wiring layer formation step, and an oxide film formation step. In addition to the above, the method for manufacturing the surface stress sensor 1 includes a forming region-side recess/protrusion pattern formation step, an exterior region-side recess/protrusion pattern formation step, a removal step, and a receptor formation step.

Note that, since the stacked body formation step, the first ion implantation step, the second ion implantation step, the heat treatment step, the wiring layer formation step, the oxide film formation step, the removal step, and the receptor formation step are the same as those in the first embodiment described above, descriptions thereof will be omitted.

### (Forming Region-Side Recess/Protrusion Pattern Formation Step and Exterior Region-Side Recess/Protrusion Pattern Formation Step)

In the forming region-side recess/protrusion pattern formation step, the forming region-side recess/protrusion pattern 52a is formed in the receptor forming region 31.

In the exterior region-side recess/protrusion pattern formation step, the exterior region-side recess/protrusion pattern 52b is formed in the exterior region 32.

In the third embodiment, the forming region-side recess/protrusion pattern 52a and the exterior region-side recess/protrusion pattern 52b are formed in such a way that, when viewed from a direction orthogonal to the thickness direction of the detection base member 20, a difference in height between the top surface Ta and the bottom surfaces Ba is greater than a difference in height between the top surface Tb and the bottom surfaces Bb.

Note that the “thickness direction of the detection base member 20” is the same direction as the “thickness direction of the membrane 22”. Therefore, the “direction orthogonal to the thickness direction of the detection base member 20” is the same direction as the “direction orthogonal to the thickness direction of the membrane 22” and the “direction in which the surface stress sensor 1 is viewed from a side surface”.

Therefore, in the third embodiment, the forming region-side recess/protrusion pattern 52a and the exterior region-side recess/protrusion pattern 52b are formed in such a way that the depth of the recessed portions formed in the forming region-side recess/protrusion pattern 52a is greater than the depth of the recessed portions formed in the exterior region-side recess/protrusion pattern 52b.

In addition, in the third embodiment, the forming region-side recess/protrusion pattern 52a and the exterior region-side recess/protrusion pattern 52b are formed in such a way that, when viewed from the thickness direction of the detection base member 20, the pitch pa is greater than the pitch pb.

Further, in the third embodiment, the forming region-side recess/protrusion pattern 52a and the exterior region-side recess/protrusion pattern 52b are formed in such a way that the total area when viewed from the thickness direction of the detection base member 20 of the bottom surfaces Ba when viewed from the thickness direction of the detection base member 20 is greater than the total area when viewed from the thickness direction of the detection base member 20 of the bottom surfaces Bb when viewed from the thickness direction of the detection base member 20.

Therefore, in the third embodiment, the forming region-side recess/protrusion pattern 52a and the exterior region-side recess/protrusion pattern 52b are formed in such a way that, when viewed from the thickness direction of the detection base member 20, the ratio of the area of the recessed portions (bottom surfaces Ba) to the total area of the forming region-side recess/protrusion pattern 52a is greater than the ratio of the area of the recessed portions (bottom surfaces Bb) to the total area of the exterior region-side recess/protrusion pattern 52b.

### (Operation and Actions)

Referring to FIGS. 1 to 49, operation and actions of the first embodiment will be described.

When, at the time of using the surface stress sensor 1 as, for example, an olfactory sensor, molecules of a gas adsorb to the receptor 30 and a strain is induced in the receptor 30, surface stress is applied to the membrane 22 and the membrane 22 is bent.

When the membrane 22 is bent, bending matching the strain induced in the receptor 30 occurs in coupling portions 26 and resistance values that flexible resistors 50 have change according to the bending occurring in the coupling portions 26.

In the surface stress sensor 1 of the third embodiment, a difference in height between the top surface Ta and the bottom surfaces Ba is greater than a difference in height between the top surface Tb and the bottom surfaces Bb.

Thus, the depth Hh is smaller than the depth Hp, and rigidity of the exterior region 32 is higher than rigidity of the receptor forming region 31. Because of this configuration, the amount of deformation of the exterior region 32 is smaller than the amount of deformation of the receptor forming region 31 at the time of bending occurring in the membrane 22, and bending matching the strain induced in the receptor 30 is better transmitted to the coupling portions 26 than a case where the depth Hh is greater than the depth Hp.

Therefore, since it becomes possible to increase the amount of deformation of the coupling portions 26 and thereby increase the amount of deformation of the flexible resistors 50 at the time of bending occurring in the membrane 22, it becomes possible to increase the amount of change in resistance values matching bending occurring in the coupling portions 26. Since, because of this configuration, it becomes possible to increase the amount of change in an electrical signal at the time of bending occurring in the membrane 22, it becomes possible to improve sensitivity of the surface stress sensor 1 and improve detection precision of the surface stress sensor 1.

In addition, in the surface stress sensor 1 of the third embodiment, a difference in height between the top surface Ta and the bottom surfaces Ba is greater than a difference in height between the top surface Tb and the bottom surfaces Bb.

The depth Hp is thus greater than the depth Hh, and it becomes possible to increase the amount of a solution forming the receptor 30 that can be retained and increase volume of the receptor 30 compared with a case where the depth Hp is greater than or equal to the depth Hh. Because of this improvement, it becomes possible to increase bending matching the strain induced in the receptor 30 at the time of bending occurring in the membrane 22, and it becomes possible to increase the amount of deformation of the flexible resistors 50.

Therefore, it becomes possible to increase the amount of change in the resistance values matching bending occurring in the coupling portions 26. Since, because of this improvement, it becomes possible to increase the amount of change in the electrical signal at the time of bending occurring in the membrane 22, it becomes possible to improve the sensitivity of the surface stress sensor 1 and improve the detection precision of the surface stress sensor 1.

It should be noted that the foregoing third embodiment is one example of the present invention, the present invention is not limited to the foregoing third embodiment, and, even when the present invention may be carried out in modes other than the embodiment, depending on designs, various changes may be made to the present invention within a scope not departing from the technical idea of the present invention

### Advantageous Effects of Third Embodiment

The surface stress sensor 1 of the third embodiment enables advantageous effects that will be described below to be attained.
(1) The depth Hp of the recessed portions forming the forming region-side recess/protrusion pattern 52a is greater than the depth Hh of the recessed portions forming the exterior region-side recess/protrusion pattern 52b.

Thus, since it becomes possible to increase the amount of deformation of the coupling portions 26 at the time of bending occurring in the membrane 22 and thereby increase the amount of deformation of the flexible resistors 50, it becomes possible to increase the amount of change in the resistance values matching bending occurring in the coupling portions 26.

Since, as a result, it becomes possible to increase the amount of change in the electrical signal at the time of bending occurring in the membrane 22, it becomes possible to improve the sensitivity of the surface stress sensor 1 and improve the detection precision of the surface stress sensor 1.
(2) The pitch pa between recessed portions adjacent to each other forming the forming region-side recess/protrusion pattern 52a when viewed from the thickness direction of the membrane 22 is greater than the pitch pb between recessed portions adjacent to each other forming the exterior region-side recess/protrusion pattern 52b when viewed from the thickness direction of the membrane 22.

Since, because of this configuration, the rigidity of the exterior region 32 is higher than the rigidity of the receptor forming region 31 and it becomes possible to increase the amount of deformation of the coupling portions 26 at the time of bending occurring in the membrane 22, it becomes possible to increase the amount of deformation of the flexible resistors 50.

As a result, it becomes possible to increase the amount of change in the resistance values matching bending occurring in the coupling portions 26 and increase the amount of change in the electrical signal at the time of bending occurring in the membrane 22. Because of this improvement, it becomes possible to improve the sensitivity of the surface stress sensor 1 and improve the detection precision of the surface stress sensor 1.

In addition, it becomes possible to increase the amount of the solution forming the receptor 30 that can be retained and increase the volume of the receptor 30. Because of this improvement, it becomes possible to increase bending matching the strain induced in the receptor 30 at the time of bending occurring in the membrane 22 and increase the amount of deformation of the flexible resistors 50.

As a result, it becomes possible to increase the amount of change in the resistance values matching bending occurring in the coupling portions 26. Since, because of this improvement, it becomes possible to increase the amount of change in the electrical signal at the time of bending occurring in the membrane 22, it becomes possible to improve the sensitivity of the surface stress sensor 1 and improve the detection precision of the surface stress sensor 1.
(3) The ratio of the area of the recessed portions (bottom surfaces Ba) to the total area of the forming region-side recess/protrusion pattern 52a when viewed from the thickness direction of the membrane 22 is greater than the ratio of the area of the recessed portions (bottom surfaces Bb) to the total area of the exterior region-side recess/protrusion pattern 52b when viewed from the thickness direction of the membrane 22.

Since, because of this configuration, the rigidity of the exterior region 32 is higher than the rigidity of the receptor forming region 31 and it becomes possible to increase the amount of deformation of the coupling portions 26 at the time of bending occurring in the membrane 22, it becomes possible to increase the amount of deformation of the flexible resistors 50.

As a result, it becomes possible to increase the amount of change in the resistance values matching bending occurring in the coupling portions 26 and increase the amount of change in the electrical signal at the time of bending occurring in the membrane 22. Because of this improvement, it becomes possible to improve the sensitivity of the surface stress sensor 1 and improve the detection precision of the surface stress sensor 1.

In addition, it becomes possible to increase the amount of the solution forming the receptor 30 that can be retained and increase the volume of the receptor 30. Because of this improvement, it becomes possible to increase bending matching the strain induced in the receptor 30 at the time of bending occurring in the membrane 22 and increase the amount of deformation of the flexible resistors 50.

As a result, it becomes possible to increase the amount of change in the resistance values matching bending occurring in the coupling portions 26. Since, because of this improvement, it becomes possible to increase the amount of change in the electrical signal at the time of bending occurring in the membrane 22, it becomes possible to improve the sensitivity of the surface stress sensor 1 and improve the detection precision of the surface stress sensor 1.

In addition, the method for manufacturing the surface stress sensor of the third embodiment enables advantageous effects that will be described below to be attained.
(4) In the forming region-side recess/protrusion pattern formation step and the exterior region-side recess/protrusion pattern formation step, the forming region-side recess/protrusion pattern 52a and the exterior region-side recess/protrusion pattern 52b are formed in such a way that the depth Hp of the recessed portions forming the forming region-side recess/protrusion pattern 52a is greater than the depth Hh of the recessed portions forming the exterior region-side recess/protrusion pattern 52b.

Thus, since it becomes possible to increase the amount of deformation of the coupling portions 26 at the time of bending occurring in the membrane 22 and thereby increase the amount of deformation of the flexible resistors 50, it becomes possible to increase the amount of change in the resistance values matching bending occurring in the coupling portions 26.

Since, as a result, it becomes possible to increase the amount of change in the electrical signal at the time of bending occurring in the membrane 22, it becomes possible to improve the sensitivity of the surface stress sensor 1 and improve the detection precision of the surface stress sensor 1.
(5) In the forming region-side recess/protrusion pattern formation step and the exterior region-side recess/protrusion pattern formation step, the forming region-side recess/protrusion pattern 52a and the exterior region-side recess/protrusion pattern 52b are formed in such a way that the pitch between recessed portions adjacent to each other forming the forming region-side recess/protrusion pattern 52a when viewed from the thickness direction of the detection base member 20 is greater than the pitch between recessed portions adjacent to each other forming the exterior region-side recess/protrusion pattern 52b when viewed from the thickness direction of the detection base member 20.

Since, because of this configuration, the rigidity of the exterior region 32 is higher than the rigidity of the receptor forming region 31 and it becomes possible to increase the amount of deformation of the coupling portions 26 at the time of bending occurring in the membrane 22, it becomes possible to increase the amount of deformation of the flexible resistors 50.

As a result, it becomes possible to increase the amount of change in the resistance values matching bending occurring in the coupling portions 26 and increase the amount of change in the electrical signal at the time of bending occurring in the membrane 22. Because of this improvement, it becomes possible to improve the sensitivity of the surface stress sensor 1 and improve the detection precision of the surface stress sensor 1.

In addition, it becomes possible to increase the amount of the solution forming the receptor 30 that can be retained and increase the volume of the receptor 30. Because of this improvement, it becomes possible to increase bending matching the strain induced in the receptor 30 at the time of bending occurring in the membrane 22 and increase the amount of deformation of the flexible resistors 50.

As a result, it becomes possible to increase the amount of change in the resistance values matching bending occurring in the coupling portions 26. Since, because of this improvement, it becomes possible to increase the amount of change in the electrical signal at the time of bending occurring in the membrane 22, it becomes possible to improve the sensitivity of the surface stress sensor 1 and improve the detection precision of the surface stress sensor 1.
(6) In the forming region-side recess/protrusion pattern formation step and the exterior region-side recess/protrusion pattern formation step, the forming region-side recess/protrusion pattern 52a and the exterior region-side recess/protrusion pattern 52b are formed in such a way that the ratio of the area of the recessed portions (bottom surfaces Ba) to the total area of the forming region-side recess/protrusion pattern 52a when viewed from the thickness direction of the detection base member 20 is greater than the ratio of the area of the recessed portions (bottom surfaces Bb) to the total area of the exterior region-side recess/protrusion pattern 52b when viewed from the thickness direction of the detection base member 20.

Since, because of this configuration, the rigidity of the exterior region 32 is higher than the rigidity of the receptor forming region 31 and it becomes possible to increase the amount of deformation of the coupling portions 26 at the time of bending occurring in the membrane 22, it becomes possible to increase the amount of deformation of the flexible resistors 50.

As a result, it becomes possible to increase the amount of change in the resistance values matching bending occurring in the coupling portions 26 and increase the amount of change in the electrical signal at the time of bending occurring in the membrane 22. Because of this improvement, it becomes possible to improve the sensitivity of the surface stress sensor 1 and improve the detection precision of the surface stress sensor 1.

In addition, it becomes possible to increase the amount of the solution forming the receptor 30 that can be retained and increase the volume of the receptor 30. Because of this improvement, it becomes possible to increase bending matching the strain induced in the receptor 30 at the time of bending occurring in the membrane 22 and increase the amount of deformation of the flexible resistors 50.

As a result, it becomes possible to increase the amount of change in the resistance values matching bending occurring in the coupling portions 26. Since, because of this improvement, it becomes possible to increase the amount of change in the electrical signal at the time of bending occurring in the membrane 22, it becomes possible to improve the sensitivity of the surface stress sensor 1 and improve the detection precision of the surface stress sensor 1.

### Variations of Third Embodiment

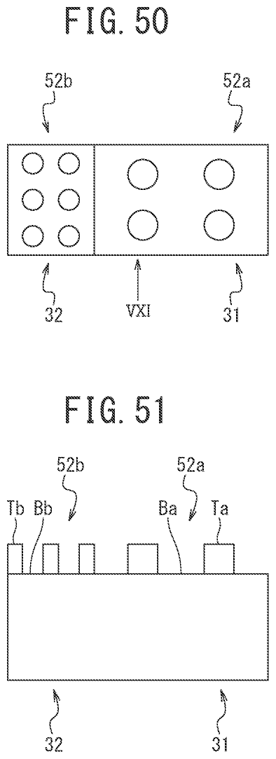

(1) Although, in the third embodiment, the forming region-side recess/protrusion pattern 52a and the exterior region-side recess/protrusion pattern 52b were formed by a plurality of recessed portions, the present invention is not limited to the configuration. That is, for example, as illustrated in the FIGS. 50 and 51, the forming region-side recess/protrusion pattern 52a and the exterior region-side recess/protrusion pattern 52b may be formed by a plurality of protruding portions.

Even when the configuration illustrated in FIGS. 50 and 51 is employed, it is possible to increase the amount of deformation of the coupling portions 26 at the time of bending occurring in the membrane 22 and increase the amount of deformation of the flexible resistors 50. Since, because of this improvement, it becomes possible to increase the amount of change in the resistance values matching bending occurring in the coupling portions 26, it becomes possible to increase the amount of change in the electrical signal at the time of bending occurring in the membrane 22 and improve the sensitivity and the detection accuracy of the surface stress sensor 1.
(2) Although, in the third embodiment, the pitch pa was defined as pitch between recessed portions adjacent to each other forming the forming region-side recess/protrusion pattern 52a, the present invention is not limited to the configuration. That is, the pitch pa may be defined as pitch between protruding portions adjacent to each other forming the forming region-side recess/protrusion pattern 52a.
(3) Although, in the third embodiment, the pitch pb was defined as pitch between recessed portions adjacent to each other forming the exterior region-side recess/protrusion pattern 52b, the present invention is not limited to the configuration. That is, the pitch pb may be defined as pitch between protruding portions adjacent to each other forming the exterior region-side recess/protrusion pattern 52b.

### REFERENCE SIGNS LIST

1 Surface stress sensor

2 Package substrate

4 Connecting portion

10 Support base member

20 Detection base member

22 Membrane

24 Holding member

26 Coupling portion

30 Receptor

31 Receptor forming region

32 Exterior region

42 Cavity portion

50 Flexible resistor

52a Forming region-side recess/protrusion pattern

52b Exterior region-side recess/protrusion pattern

60 First silicon substrate

62 Recessed portion

64 Second silicon substrate

66 Stacked body

68 Silicon oxide film

70 Flexible resistor region

72 Low resistance region

74 Silicon nitride film

76 Hole

78 Laminated film

80 Metal film

82 Wiring layer

84 Membrane setting region

85 Removal region

86 PAD

87 Flat surface region

88 Recessed portion region

90 Connecting layer

92 Sacrificial layer

94 Oxide film

VL1 Virtual straight line passing the center of a membrane

VL2 Straight line orthogonal to the straight line VL1

SO Silicon oxide film

1. A surface stress sensor including:
a receptor configured to be deformed according to an adsorbed substance; and
a membrane configured to be bent by applied surface stress,
the surface stress sensor comprising:
a holding member arranged on an outer side of the membrane;
at least a pair of coupling portions configured to couple the membrane and the holding member;
a flexible resistor configured to have a resistance value changing according to bending induced in the coupling portions; and
a forming region-side recess/protrusion pattern formed on a surface of the membrane and formed with a pattern in which a plurality of protruding portions or a plurality of recessed portions continue,
wherein the membrane includes a first surface region, the first surface region being a region including a center of the surface, and a second surface region, the second surface region being a region located closer to the holding member than the first surface region,
the forming region-side recess/protrusion pattern is formed in the first surface region, and
the receptor is present in gaps formed by a plurality of protruding portions or a plurality of recessed portions forming the forming region-side recess/protrusion pattern.

2. The surface stress sensor according to claim 1, wherein the second surface region is a smooth surface.

3. The surface stress sensor according to claim 1 further comprising
an exterior region-side recess/protrusion pattern formed in the second surface region and formed with a pattern in which a plurality of protruding portions or a plurality of recessed portions continue,
wherein the exterior region-side recess/protrusion pattern is a pattern having a degree of roughness enabling a solution to be prevented from infiltrating into gaps formed by a plurality of protruding portions or a plurality of recessed portions forming the exterior region-side recess/protrusion pattern.

4. The surface stress sensor according to claim 3, wherein the exterior region-side recess/protrusion pattern is formed in a shape matching physical properties of the receptor.

5. The surface stress sensor according to claim 3, wherein each of the protruding portions or the recessed portions forming the exterior region-side recess/protrusion pattern is formed in a circle when viewed from a thickness direction of the membrane.

6. The surface stress sensor according to claim 3, wherein a degree of roughness of the forming region-side recess/protrusion pattern is lower than a degree of roughness of the exterior region-side recess/protrusion pattern.

7. The surface stress sensor according to claim 1, further comprising
an exterior region-side recess/protrusion pattern formed in the second surface region and formed with a pattern in which a plurality of protruding portions or a plurality of recessed portions continue,
wherein depth of recessed portions formed in the forming region-side recess/protrusion pattern is greater than depth of recessed portions formed in the exterior region-side recess/protrusion pattern.

8. The surface stress sensor according to claim 1, further comprising
an exterior region-side recess/protrusion pattern formed in the second surface region and formed with a pattern in which a plurality of protruding portions or a plurality of recessed portions continue,
wherein pitch between the protruding portions or the recessed portions adjacent to each other forming the forming region-side recess/protrusion pattern when viewed from a thickness direction of the membrane is greater than pitch between the protruding portions or the recessed portions adjacent to each other forming the exterior region-side recess/protrusion pattern when viewed from the thickness direction of the membrane.

9. The surface stress sensor according to claim 1, further comprising
an exterior region-side recess/protrusion pattern formed in the second surface region and formed with a pattern in which a plurality of protruding portions or a plurality of recessed portions continue,
wherein a ratio of area of recessed portions to total area of the forming region-side recess/protrusion pattern when viewed from a thickness direction of the membrane is greater than a ratio of area of recessed portions to total area of the exterior region-side recess/protrusion pattern when viewed from the thickness direction of the membrane.

10. The surface stress sensor according to claim 1, wherein the forming region-side recess/protrusion pattern is formed in a shape matching physical properties of the receptor.

11. The surface stress sensor according to claim 1, wherein each of the protruding portions or the recessed portions forming the forming region-side recess/protrusion pattern is formed in a circle when viewed from a thickness direction of the membrane.

12. A method for manufacturing a surface stress sensor comprising
a forming region-side recess/protrusion pattern formation step of forming a forming region-side recess/protrusion pattern, the forming region-side recess/protrusion pattern being formed with a pattern in which a plurality of protruding portions or a plurality of recessed portions continue, in a first surface region, the first surface region being a preset region including a center of a surface of a detection base member,
wherein, in the forming region-side recess/protrusion pattern formation step, the method forms the forming region-side recess/protrusion pattern in such a way that the forming region-side recess/protrusion pattern has a degree of roughness allowing a solution to be present in gaps formed by a plurality of protruding portions or a plurality of recessed portions forming the forming region-side recess/protrusion pattern.

13. The method for manufacturing the surface stress sensor according to claim 12 further comprising
a removal step of, by removing a circumference of a region in which the forming region-side recess/protrusion pattern is formed within the detection base member, forming a membrane configured to be bent by applied surface stress, a holding member arranged on an outer side of a center of the membrane, at least a pair of coupling portions configured to couple the membrane and the holding member, and a flexible resistor configured to have a resistance value changing according to bending induced in the coupling portions,
wherein the method performs the forming region-side recess/protrusion pattern formation step and the removal step simultaneously.

14. The method for manufacturing the surface stress sensor according to claim 12, further comprising
an exterior region-side recess/protrusion pattern formation step of forming an exterior region-side recess/protrusion pattern, the exterior region-side recess/protrusion pattern being formed with a pattern in which a plurality of protruding portions or a plurality of recessed portions continue, in a second surface region, the second surface region being a region surrounding a circumference of the first surface region within the surface,
wherein, in the exterior region-side recess/protrusion pattern formation step, the method forms the exterior region-side recess/protrusion pattern in such a way that the exterior region-side recess/protrusion pattern has a degree of roughness enabling a solution to be prevented from infiltrating into gaps formed by a plurality of protruding portions or a plurality of recessed portions forming the exterior region-side recess/protrusion pattern.

15. The method for manufacturing the surface stress sensor according to claim 14, wherein the method performs the forming region-side recess/protrusion pattern formation step and the exterior region-side recess/protrusion pattern formation step simultaneously.

16. The method for manufacturing the surface stress sensor according to claim 14, further comprising
a removal step of, by removing a circumference of a region in which the forming region-side recess/protrusion pattern is formed within the detection base member, forming a membrane configured to be bent by applied surface stress, a holding member arranged on an outer side of a center of the membrane, at least a pair of coupling portions configured to couple the membrane and the holding member, and a flexible resistor configured to have a resistance value changing according to bending induced in the coupling portions,
wherein the method performs the exterior region-side recess/protrusion pattern formation step and the removal step simultaneously.

17. The method for manufacturing the surface stress sensor according to claim 14, wherein, in the forming region-side recess/protrusion pattern formation step and the exterior region-side recess/protrusion pattern formation step, the method forms the forming region-side recess/protrusion pattern and the exterior region-side recess/protrusion pattern in such a way that a degree of roughness of the forming region-side recess/protrusion pattern is lower than a degree of roughness of the exterior region-side recess/protrusion pattern.

18. The method for manufacturing the surface stress sensor according to claim 12, further comprising
an exterior region-side recess/protrusion pattern formation step of forming an exterior region-side recess/protrusion pattern, the exterior region-side recess/protrusion pattern being formed with a pattern in which a plurality of protruding portions or a plurality of recessed portions continue, in a second surface region, the second surface region being a region surrounding a circumference of the first surface region within the surface,
wherein, in the forming region-side recess/protrusion pattern formation step and the exterior region-side recess/protrusion pattern formation step, the method forms the forming region-side recess/protrusion pattern and the exterior region-side recess/protrusion pattern in such a way that depth of recessed portions formed in the forming region-side recess/protrusion pattern is greater than depth of recessed portions formed in the exterior region-side recess/protrusion pattern.

19. The method for manufacturing the surface stress sensor according to claim 12, further comprising
an exterior region-side recess/protrusion pattern formation step of forming an exterior region-side recess/protrusion pattern, the exterior region-side recess/protrusion pattern being formed with a pattern in which a plurality of protruding portions or a plurality of recessed portions continue, in a second surface region, the second surface region being a region surrounding a circumference of the first surface region within the surface,
wherein, in the forming region-side recess/protrusion pattern formation step and the exterior region-side recess/protrusion pattern formation step, the method forms the forming region-side recess/protrusion pattern and the exterior region-side recess/protrusion pattern in such a way that pitch between the protruding portions adjacent to each other or the recessed portions adjacent to each other forming the forming region-side recess/protrusion pattern when viewed from a thickness direction of the detection base member is greater than pitch between the protruding portions adjacent to each other or the recessed portions adjacent to each other forming the exterior region-side recess/protrusion pattern when viewed from the thickness direction of the detection base member.

20. The method for manufacturing the surface stress sensor according to claim 12, further comprising
an exterior region-side recess/protrusion pattern formation step of forming an exterior region-side recess/protrusion pattern, the exterior region-side recess/protrusion pattern being formed with a pattern in which a plurality of protruding portions or a plurality of recessed portions continue, in a second surface region, the second surface region being a region surrounding a circumference of the first surface region within the surface,
wherein, in the forming region-side recess/protrusion pattern formation step and the exterior region-side recess/protrusion pattern formation step, the method forms the forming region-side recess/protrusion pattern and the exterior region-side recess/protrusion pattern in such a way that a ratio of area of recessed portions to total area of the forming region-side recess/protrusion pattern when viewed from a thickness direction of the detection base member is greater than a ratio of area of recessed portions to total area of the exterior region-side recess/protrusion pattern when viewed from the thickness direction of the detection base member.
